(19) United States
(12) Patent Application Publication
(10) Pub. No.: US 2026/0280535 A1
(43) Pub. Date: Sep. 17, 2026

(54) Clock-Controlled Transistor Circuitry and Methods

(71) Applicant: Arm Limited, Cambridge (GB)

(72) Inventors: Subramanya Ravindra Shindagikar, Hubli (IN); Yunpeng Cai, Nice (FR); Yves Thomas Laplanche, Valbonne (FR); Steve Dao, Austin, TX (US)

(21) Appl. No.: 19/170,038

(22) Filed: Apr. 3, 2025

(30) Foreign Application Priority Data
Mar. 11, 2025 (IN) 202541021965

(51) Int. Cl. H03K 3/037; H03K 3/012

(52) U.S. Cl. CPC H03K 3/0372; H03K 3/012

(57) ABSTRACT

According to one implementation, a circuit includes at least one flip-flop; and clock-sharing circuitry. The clock-sharing circuitry includes a clock-controlled transistor device coupled to at least one shared node of the at least one flip-flop, where the at least one shared node includes at least one of: an intra-flop shared node coupled between two or more logic structures within the at least one flip-flop; and an inter-flop shared node coupled between at least two flip-flops. In one implementation, a method includes; 1) receiving an input clock signal; and 2) distributing the input clock signal to at least one flip-flop, where distributing the input signal includes: coupling the clock signal to a shared clock-controlled transistor device; and sharing the shared clock-controlled transistor device at: an intra-flop shared node between two or more logic structures within a flip-flop; an inter-flop shared node between at least two flip-flops; or both intra-flop and inter-flop shared nodes.

### I. FIELD

The present disclosure is generally related to clock-controlled transistor circuitry and methods.

### II. DESCRIPTION OF RELATED ART

This section is intended to provide information relevant to understanding various technologies described herein. As the section's heading implies, this is a discussion of related art that in no way implies that the discussion is prior art. Generally, related art may or may not be considered prior art. Any statement in this section should be read in this light, and not as admission of prior art.

Flip-flops are fundamental building blocks in digital circuits, providing data storage and synchronization in sequential logic systems. As integrated circuits (ICs) grow in complexity, managing power consumption and clock distribution becomes increasingly challenging. Conventional flip-flop architectures rely on dedicated clock-controlled transistors at each stage, including the master and slave latches. In large-scale systems, this results in excessive power consumption, increased clock loading, and clock skew, all of which degrade performance. Additionally, the high number of clock-controlled transistors within each flip-flop places a significant burden on the clock distribution network, often requiring extra buffers and inverters to maintain signal integrity.

As circuits incorporate more flip-flops, the number of clock-driven transistors increases proportionally, leading to greater switching activity and higher overall power dissipation. Multi-bit implementations further exacerbate this inefficiency, as each bitcell adds additional clock-controlled transistors without improving clocking efficiency. Given the growing demand for high-performance and low-power applications, there is a critical need for a more scalable and power-efficient flip-flop design that can address these challenges while maintaining reliable timing characteristics.

### III. BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1A illustrates diagrams of an example circuit layout in accordance with various implementations described herein.

FIG. 1B is a diagram of an example circuit layout in accordance with various implementations described herein.

FIG. 2A is a schematic diagram of an example circuit in accordance with various implementations described herein.

FIG. 2B is a schematic diagram of an example circuit in accordance with various implementations described herein.

FIG. 2C is a schematic diagram of an example circuit in accordance with various implementations described herein.

FIG. 2D is a schematic diagram of an example circuit in accordance with various implementations described herein.

FIG. 3 is a schematic diagram of an example circuit in accordance with various implementations described herein.

FIG. 4 is a schematic diagram of an example circuit in accordance with various implementations described herein.

FIG. 5A is a diagram of an example circuit layout in accordance with various implementations described herein.

FIG. 5B is a diagram of an example circuit layout in accordance with various implementations described herein.

FIG. 5C is a diagram of an example circuit layout in accordance with various implementations described herein.

FIG. 6A is a schematic diagram of an example circuit in accordance with various implementations described herein.

FIG. 6B is a schematic diagram of an example circuit in accordance with various implementations described herein.

FIG. 6C is a schematic diagram of an example circuit in accordance with various implementations described herein.

FIG. 6D is a schematic diagram of an example circuit in accordance with various implementations described herein.

FIG. 6E is a schematic diagram of an example circuit in accordance with various implementations described herein.

FIG. 7 is a schematic diagram of an example circuit in accordance with various implementations described herein.

FIG. 8 is a schematic diagram of an example circuit in accordance with various implementations described herein.

FIG. 9A is a diagram of an example circuit layout in accordance with various implementations described herein.

FIG. 9B is a diagram of an example circuit layout in accordance with various implementations described herein.

FIG. 10 is a schematic diagram of an example circuit in accordance with various implementations described herein.

FIG. 11 is a schematic diagram of an example circuit in accordance with various implementations described herein.

FIG. 12 is a schematic diagram of an example circuit in accordance with various implementations described herein.

FIG. 13 is a schematic diagram of an example circuit in accordance with various implementations described herein.

FIG. 14 is a schematic diagram of an example circuit in accordance with various implementations described herein.

FIG. 15 is a schematic diagram of an example circuit in accordance with various implementations described herein.

FIG. 16 is an operational method in accordance with various implementations described herein.

FIG. 17 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### IV. DETAILED DESCRIPTION

Implementations of the present disclosure are described below with reference to the drawings. In the description, common features are designated by common reference numbers throughout the drawings.

According to one implementation of the present disclosure, a circuit includes at least one flip-flop; and clock-sharing circuitry. The clock-sharing circuitry includes a clock-controlled transistor device coupled to at least one shared node of the at least one flip-flop, where the at least one shared node includes at least one of: an intra-flop shared node coupled between two or more logic structures within the at least one flip-flop; and an inter-flop shared node coupled between at least two flip-flops.

According to one implementation, a method includes: 1) receiving an input clock signal; and 2) distributing the input clock signal to at least one flip-flop, where distributing the input signal includes: coupling the clock signal to a shared clock-controlled transistor device; and sharing the shared clock-controlled transistor device at: an intra-flop shared node between two or more logic structures within a flip-flop; an inter-flop shared node between at least two flip-flops; or both intra-flop and inter-flop shared nodes.

Inventive aspects, as described herein, introduce optimized flip-flop architectures that substantially reduce transistor count, clock loading, and power consumption through strategic transistor sharing within and across flip-flops. Conventional designs typically require dedicated clock-controlled transistors for each latch and flip-flop stage, creating unnecessary redundancy and increasing the complexity of the clock distribution network. In contrast, the present invention addresses these inefficiencies by providing clock-sharing circuitry, including clock-controlled transistors coupled to shared nodes, enabling intra-flop transistor sharing within individual flip-flops, inter-flop transistor sharing between multiple flip-flops, or combinations thereof.

In certain embodiments, single-bit flip-flops advantageously employ intra-flop transistor sharing by merging transistor nodes between two or more internal logic structures. For instance, master latch and slave latch nodes within a flip-flop may be coupled to a common shared node, facilitating the use of a single clock-controlled transistor (e.g., a shared NFET or PFET transistor). The master latch may include a clock-gated, cross-coupled logic structure with an integrated input multiplexer, and the slave latch may comprise a glitchless tristate driver configured to securely propagate and store data. Advantageously, these shared-node arrangements significantly reduce the total number of transistors directly controlled by the clock, minimizing clock load, timing skew, and power dissipation while preserving stable latch operation.

Beyond single-bit implementations, inventive architectures, as described herein, extend transistor-sharing strategies to multi-bit configurations by introducing inter-flop clock transistor sharing across multiple flip-flops. In conventional approaches, each flip-flop independently requires separate clock-controlled transistors, thereby duplicating transistor structures and increasing clock load. Advantageously, the present invention mitigates this redundancy by providing at least one shared clock-controlled transistor (e.g., shared foot transistor in NAND-based configurations, or shared head transistor in NOR-based configurations) coupled to inter-flop shared nodes common across multiple flip-flops. Such arrangements effectively eliminate redundant clock-controlled transistors, thereby significantly reducing transistor count, clock network complexity, and power consumption.

To further enhance efficiency and scalability, the present invention supports multi-bit flip-flop implementations that utilize a single clock inverter circuitry to distribute inverted clock signals across multiple flip-flop bits. Such implementations advantageously reduce clock transistor loading, improve clock signal integrity, and decrease power dissipation compared to conventional configurations. Various multi-bit configurations disclosed herein beneficially achieve transistor-count optimizations defined by (4N+1), (3N+1), or even a minimal (2N+1) transistor load for N flip-flop bits. Advantageously, these transistor sharing techniques are applicable to both NAND-based and NOR-based flip-flop architectures, providing designers with flexibility in selecting appropriate circuit topologies based on desired performance, power, and area (PPA) tradeoffs.

Accordingly, the present invention achieves significant advantages by strategically implementing intra-flop and inter-flop transistor sharing in flip-flop circuits. Inventive techniques substantially lower transistor count, minimize clock-loading complexity, reduce power consumption, and ensure robust timing and operational stability across both single-bit and multi-bit configurations. Advantageously, these optimized flip-flop architectures are scalable, flexible, and compatible with existing clock distribution methodologies, ensuring reliable performance improvements in advanced integrated circuit designs.

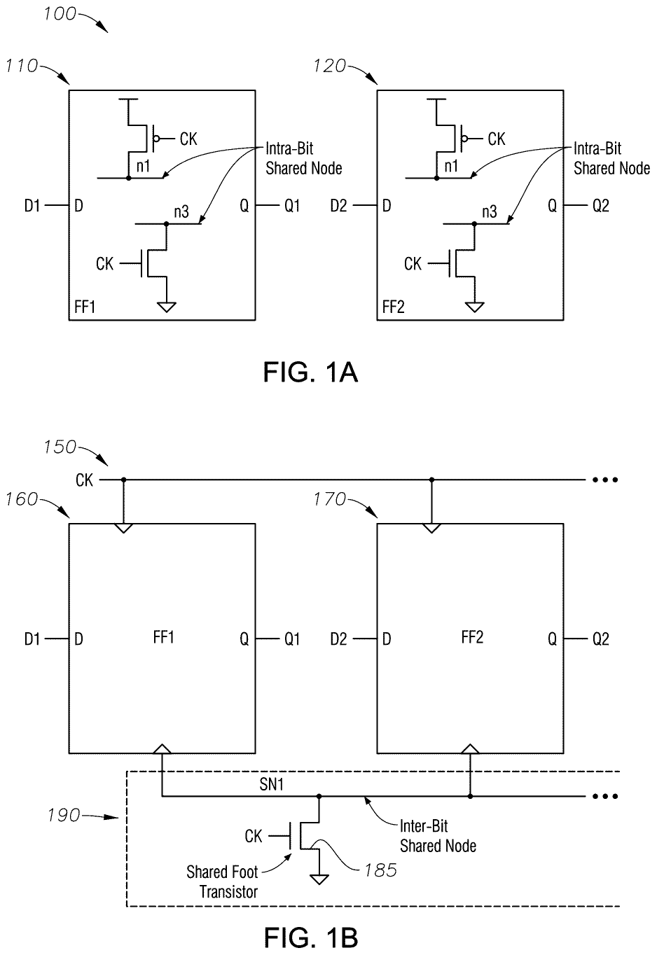

Certain definitions have been provided herein for reference. A clock-sharing circuit refers to circuitry within flip-flop architectures that includes at least one clock-controlled transistor coupled to one or more shared nodes to minimize redundant clock-driven transitions. Specifically, the clock-sharing circuit provides intra-flop transistor sharing (within a single flip-flop), inter-flop transistor sharing (across multiple flip-flops), or both, thereby significantly reducing transistor count, clock loading, and power consumption. As may be appreciated, the clock-sharing circuitry, as described herein, includes each of the embodiments having clock-related sharing circuit elements. For instance, dashed lines in the illustrative drawings are not intended to be limiting of the circuit sharing circuitry but just to depict certain shared elements. Hence, the circuit-sharing circuitry includes all of the circuit elements and nodes in each of the respective implementations of FIGS. 1-15.

A pseudo-master latch is a latch structure within a flip-flop comprising cross-coupled logic gates (e.g., NAND or NOR gates), a clock-gated logic structure that conditions data inputs, an integrated input multiplexer, and in certain cases, an associated keeper sub-circuit. Unlike conventional master latches with full inverter loops, the pseudo-master latch stores and propagates data using optimized clock-sharing circuitry to reduce transistor count while reliably maintaining internal logic states.

A single-phase clocked-multiplexer (single-phase clocked-mux) is a multiplexer circuit configured to select between multiple data input signals based on a single-phase clock signal (CK). In certain implementations, the single-phase clocked-mux includes clock-controlled selection circuitry integrated within a pseudo-master latch to reduce timing complexity and transistor redundancy, eliminating the need for complementary clock signals.

A glitchless tri-state inverter (e.g., tristate write port) refers to a circuit element within a slave latch that provides controlled data propagation, ensures stable logic state retention, and minimizes transient glitches caused by clock-signal transitions. Specifically, the glitchless tri-state inverter comprises a tri-state driver and an associated storage element, where transitions occur only under controlled, synchronized clock conditions, enhancing data integrity and timing reliability.

A keeper circuit is a circuit component coupled to a clocked internal node that maintains a predefined logic state, preventing unintended voltage transitions. Particularly useful in clock-sharing architectures, the keeper circuit typically includes at least one clock-controlled transistor and a feedback structure that reinforces the stored logic state during clock inactivity, thereby preserving node stability.

A clock-controlled transistor is a transistor (e.g., NFET or PFET) within flip-flop circuitry that transitions states based on a clock signal (CK or NCK). Clock-controlled transistors can be coupled to shared nodes to facilitate intra-flop or inter-flop transistor sharing. In certain configurations, such clock-controlled transistors include a shared foot transistor (in NAND-based designs, coupled to a low power supply potential) or a shared head transistor (in NOR-based designs, coupled to a high power supply potential), optimizing transistor usage and reducing clock loading.

A shared foot transistor is a clock-controlled NFET transistor positioned at the bottom-most transistor stack of a NAND-based logic structure within one or more flip-flops. The shared foot transistor is coupled to a low power supply (e.g., ground), enabling efficient intra-flop or inter-flop sharing across multiple NAND logic structures, thereby significantly reducing transistor redundancy and clock network complexity.

A shared head transistor is a clock-controlled PFET transistor positioned at the top-most transistor stack of a NOR-based logic structure within one or more flip-flops. The shared head transistor is coupled to a high power supply (e.g., VDD), facilitating efficient intra-flop or inter-flop sharing across multiple NOR logic structures, thereby significantly reducing transistor redundancy and minimizing clock load.

A shared clock-control node refers to a circuit node electrically coupled to multiple clock-controlled transistors, enabling intra-flop transistor sharing within a single flip-flop, inter-flop transistor sharing across multiple flip-flops, or both. Such shared clock-control nodes advantageously reduce the number of transistors directly coupled to the clock distribution network, improving signal integrity and timing accuracy.

A clock inverter is circuitry configured to generate an inverted clock signal (NCK) from an original clock signal (CK). Advantageously employed in multi-bit flip-flop implementations, the clock inverter efficiently distributes a single-phase inverted clock signal across multiple flip-flops, minimizing clock signal degradation, reducing overall transistor load, and preserving synchronization.

A pass gate refers to pass-transistor logic comprising complementary transistor devices (e.g., PFET and NFET) operating as switches. An inverter comprises coupled PFET and NFET transistor devices configured to invert an input signal, providing an inverted output signal.

FIGS. 1A and 1B illustrate clock-sharing techniques, in flip-flop circuits (e.g., NAND-based configurations) 100 and 150, respectively, according to example implementations. As illustrated, the circuits 100, 150 are designed to minimize power consumption by reducing the number of clock-controlled transistors. In various aspects, two distinct clock-sharing approaches are shown: intra-bit (or intra-flop) clock sharing in FIG. 1A and inter-bit (or inter-flop) clock sharing in FIG. 1B. In such aspects, the clock signal CK is a single-phase clock signal used throughout the circuit to control data storage and propagation.

Referring to FIG. 1A, a flip-flop circuit 100 is shown, incorporating intra-flop clock sharing to reduce the number of clock-controlled transistors within a single flip-flop. As illustrated, as one example, flip-flop circuit 100 includes structurally identical (e.g., replica) flip-flops (FF1) 110 and (FF2) 120. In this configuration, two or more internal nodes within each flip-flop are “merge-able”, thus allowing for the removal of a CK transistor; and hence, the quantity of CK-driven switching elements may be minimized. As shown, since FF1 110 and FF2 120 share clock-controlled transistors internally, the optimization remains confined within each individual flip-flop, ensuring that the sharing would not affect external components. By reducing the number of CK-controlled transistors while preserving proper data storage and propagation, intra-flop clock sharing improves circuit efficiency and lowers power consumption.

Referring to FIG. 1B, a flip-flop circuit 150 is shown, illustrating inter-flop clock sharing, where clock-controlled transistors are shared across multiple flip-flops. As illustrated, in one example, flip-flop circuit 150 includes flip-flops 160 and 170, that are coupled to a shared foot transistor 185 connected to the CK distribution network 190. Unlike the intra-flop approach in FIG. 1A, where clock-sharing is confined within individual flip-flops, the inter-flop configuration moves a clock-controlled transistor to a “higher-level” of hierarchy, allowing multiple flip-flops to share a single CK transistor. As shown, the shared foot transistor 185 has one of its terminals (e.g., drain terminal) coupled to a common node among multiple flip-flops, reducing the overall number of clock-controlled transistors across the circuit 150. This configuration enables a more efficient clocking architecture, particularly in multi-bit designs, by eliminating redundant switching elements while maintaining synchronized clock operation.

While FIGS. 1A and 1B illustrate NAND-based clock-sharing configurations that use NFET transistors coupled to ground, alternative NOR-based implementations can also be employed (not shown in FIGS. 1A-1B). For such configurations, rather than an NFET being coupled to ground, a PFET is coupled to power (e.g., VDD), forming a De Morgan equivalent design. The NOR-based architecture follows the same principles of intra-and inter-flop clock sharing but modifies the transistor placement to optimize pull-up network behavior instead of pull-down behavior. The NOR-based clock-sharing approach will be described in greater detail in later sections.

FIGS. 1A and 1B demonstrate two distinct clock-sharing techniques that reduce the number of clock-controlled transistors, improving power efficiency and scalability. Intra-flop clock sharing, as shown in FIG. 1A, minimizes redundant clocked transistors within a flip-flop, while inter-flop clock sharing, as shown in FIG. 1B, extends this optimization across multiple flip-flops using shared transistors within the clock distribution network. These techniques enable lower transistor counts, reduced power consumption, and scalable clocking solutions for high-performance circuits.

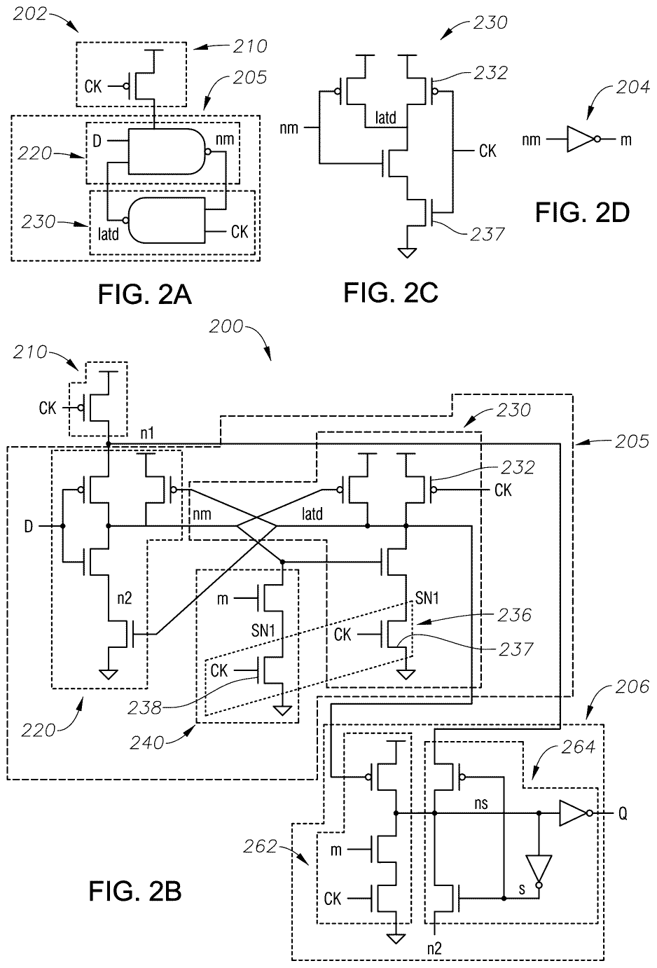

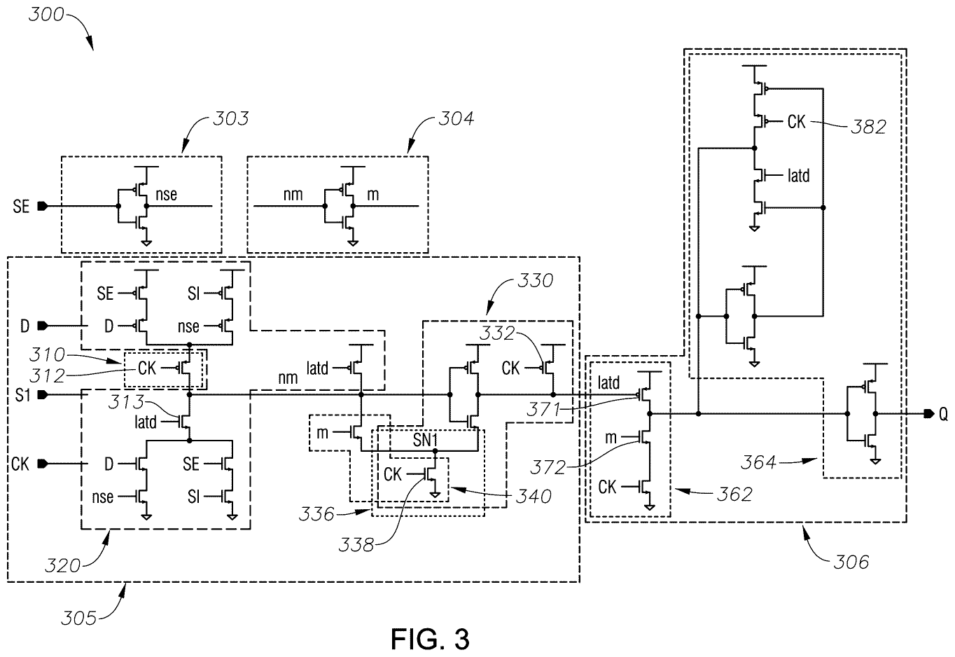

Referring to FIGS. 2A-2D, an example flip-flop circuit 200 (e.g., a NAND-based architecture) is shown according to example implementations. The circuit 200 incorporates a single-phase, low-power clock-sharing architecture to minimize clock-controlled transistors while ensuring stable data storage and propagation. As illustrated, in various implementations, the circuit includes: a clock circuitry 210, a master latch 205 (e.g., a “pseudo” master latch) and a slave latch (e.g., a “glitchless” slave latch) 206. In certain examples, as shown, the master latch 205 includes: a first logic structure 220 (e.g., a first-NAND gate), a second logic structure 230 (e.g., a second-NAND gate), a keeper circuit 240. In certain cases, the slave latch 260 includes a glitchless tri-state inverter 262 (e.g., tristate write port) and a feedback storage loop 264. Advantageously, in such an example, the clock circuitry 210 generates a single-phase clock signal CK to control data transitions throughout the circuit 200 without requiring clock inversion or buffering.

As depicted, FIG. 2A illustrates a circuit portion 210 shown as a logic block diagram. The circuit portion 210 includes the clock circuitry 210 and the master latch 205, where the master latch includes a cross-coupled NAND, with first and second logic structures 210, 220. In various implementations, as shown in FIG. 2B, the master latch 205 (e.g., including the first logic structure 220, the second logic structure 230, and (integrated) keeper circuit 240) processes and stores incoming data before transferring it to the slave latch 206. The first logic structure 220 operates as a clock-gated NAND gate, whose switching behavior is controlled by CK. The second logic structure 230, also implemented as a NAND gate, is coupled to the output of the first logic structure 220 and interfaces with the keeper circuit 240, which maintains the stability of internal nodes when CK is inactive. The keeper circuit 240 ensures that the stored value remains unchanged by holding a predefined logic state, preventing unintended transitions.

As shown, FIG. 2C highlights a transistor-level implementation of the second logic structure (e.g., a second NAND-gate), where an NFET device (e.g., NFET device 237) at the bottom of the stack is configured for clock-sharing. For instance, in an intra-sharing example, as shown, in FIG. 2B, by the “merging” of the nodes SN1 in the keeper circuitry 240, the distinct NFET device 238 of the keeper circuitry and the NFET device 237 can be replaced with a common CK NFET device (e.g. a reduction to one CK NFET device at clock-sharing circuitry 236). In addition, in such implementations, the PFET transistor 232 is coupled to CK, ensuring that when CK is low, the latd node is precharged to a high state. In addition, alternatively, in an inter-sharing example (not shown in FIGS. 2A-2D, but explained in later implementations), the NFET device 237 can be shared across two or more flops. Such configurations supports clock-sharing across multiple flip-flops, allowing for the removal redundant CK-controlled transistors in multi-bit implementations.

FIG. 2D illustrates the derivation of the m signal, showing its relation to nm and its role in controlling transitions in the slave latch 206. As explained later, with reference to FIG. 3, the interplay between these signals ensures accurate data transfer between the master latch 205 and the slave latch 206 while minimizing redundant switching activity.

Referring to FIG. 3, an example flip-flop circuit 300 (e.g., NAND-configuration) is shown according to example implementations. As illustrated, the circuit 300 is an example expansion of FIG. 2B, configured to achieve optimized power, performance, and area (PPA) efficiency. In certain aspects, the circuit 300 includes clock circuitry 310, a master latch 305, and a slave latch 306. The master latch 305 includes two cross-coupled NAND logic structures: a first NAND gate (e.g., first logic structure) 320 and a second NAND gate (e.g., second logic structure) 330. In certain implementations, as shown, the first NAND gate 320 is clock-gated and at least partially integrates an input multiplexer (e.g., scan mux) and a keeper sub-circuit 340. The keeper sub-circuit ensure node stability during specific transitions. In some implementations, the keeper sub-circuit may be coupled to an output node of the first NAND gate 320. The slave latch 306 includes a tri-state inverter 362 (e.g., a glitch-less tristate inverter, tristate write port) and a feedback storage loop 364. In addition, advantageously, in circuit 300 certain elements may be shared. For instance, in FIG. 3, clock-sharing circuitry 336 shares CK NFET transistor 338 (e.g., a clock-controlled transistor) and a common node SN1 (e.g., an intra-shared node). Advantageously, the circuit 300 is single-phase clocked, utilizing the clock signal CK without requiring additional inversion or buffering. Also depicted are scan enable (SE) inverter circuitry 303 configured to generate nse signal from scan enable (se) signal, and a nm inverter circuitry 304 configured to generate m signal from nm signal.

In various aspects, the input multiplexer, integrated into the first NAND gate 322, selects between a scan input (SI) and a data input (D), replacing the PFET/NFET input structure shown previously. The first NAND gate 322 includes a latd-coupled transistor, an integrated multiplexer structure with a PFET transistor coupled to node nm and an NFET transistor coupled to node m, and a CK-coupled NFET transistor. During an example operation, when the clock signal CK is low (logic 0), data propagates through the input multiplexer into the first NAND gate 322. Specifically, the CK-gated PMOS transistor 312 within the input multiplexer turns on, precharging node latd to a digital high (e.g., VDD). The latd-gated NMOS transistor 313 also activates, enabling data writing from the multiplexer output to node nm. Also, the keeper sub-circuit 340, formed by node m (generated by an inverter from node nm) and the CK-controlled transistor 338, maintains the stability of node nm. Particularly, the keeper sub-circuit 340 ensures node nm does not float to an unintended logic state if the data input transitions from logic 1 to logic 0 while CK remains high.

At the rising edge of the clock signal CK (e.g., transitioning from logic 0 to logic 1), data stored at node nm propagates into the second NAND gate 330, which previously precharged node latd to a logic high during CK=0. Upon CK transitioning high, the CK-controlled PMOS transistor 332 of the second NAND gate 332 turns off, stopping the precharge action, while the CK-coupled NFET transistor 338 becomes conductive, enabling data from node nm to transfer to node latd. Node latd now accurately reflects the logic state of the input data. Advantageously, by merging the keeper circuit 340 and the second NAND gate 332 to share a CK transistor (e.g., CK transistor 328), transistor count is minimized. The slave latch 306, specifically the tri-state inverter 362, controls data propagation to output node Q. When CK=0, node latd remains high, deactivating the tri-state inverter 362 and allowing feedback storage loop 364 to latch the previous state, maintaining stable output. Upon CK transitioning from logic 0 to logic 1, tri-state inverter 362 becomes transparent, enabling node latd data to propagate to output node Q.

In a first operational example, if the data input is logic 1, node nm becomes logic 0, resulting in node latd maintaining a logic 1 at CK's rising edge. Node m (inverted from node nm) is logic 1, activating the middle transistor 372 in the tri-state inverter 362, driving the output node to logic 0 internally. Concurrently, the feedback storage loop 364 stops latching, as its CK transistor 382 is disabled, avoiding contention at the output node Q. Consequently, output node Q correctly outputs logic 1, matching the initial input data.

In a second operational example, if the data input is logic 0, node nm becomes logic 1, causing node latd to discharge to logic 0 during CK's transition from 0 to 1. The PMOS transistor 371 in tri-state inverter 362 activates due to latd being 0, pulling output node Q to logic 0. The feedback storage loop 364 is entirely disabled, preventing any conflicts. Consequently, output Q accurately outputs logic 0, consistent with the data input.

Based on the above, the circuit 300 thus demonstrates optimized single-phase operation with significantly improved PPA by incorporating a merged clock-controlled transistor and integrated multiplexer logic. Critical node latd is optimized by reducing transistor count, substantially decreasing switching power due to its high (approximately 50%) switching probability. Moreover, the inventive design leverages two primary advantages: firstly, cross-coupled NAND logic structures sharing a CK transistor to reduce transistor overhead, and secondly, the glitchless tri-state inverter 362 within the slave latch, driven uniquely by node m (inverted from node nm), effectively eliminating potential glitches at the slave latch 306 output, thereby enhancing reliability and performance.

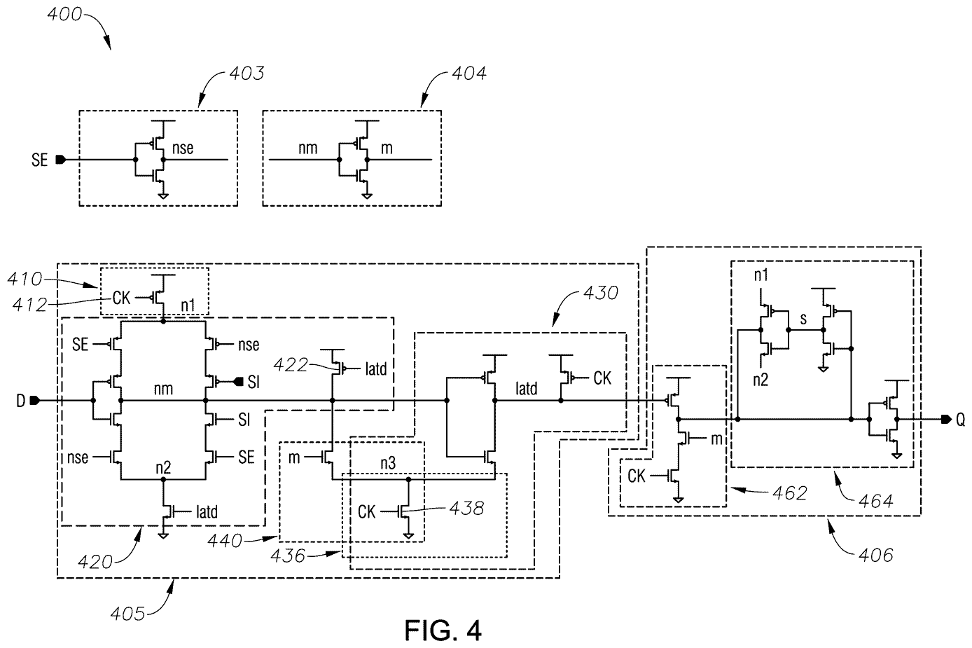

Referring to FIG. 4, an example flip-flop circuit 400 (e.g., NAND-configuration), according to example implementations. The circuit 400 shares many features, operations, and circuit elements substantially identical to those described above with reference to FIG. 3. As illustrated, the circuit 400 similarly includes a clock circuitry 410, a master latch 405, and a slave latch 406. In certain aspects, the master latch 405 similarly includes two cross-coupled NAND logic structures: a first NAND gate (e.g., first logic structure) 420 and a second NAND gate (e.g., second logic structure) 430. In certain implementations, as shown, the first NAND gate 420 is similarly clock-gated and integrates an input multiplexer (e.g., scan mux), and is coupled to a keeper sub-circuit 440 (with node m and CK transistor, configured identically to keeper sub-circuit 340 of FIG. 3). The slave latch 406 similarly includes a tri-state inverter 462 (e.g., a glitch-less tristate inverter, tristate write port) and a feedback storage loop 464. The circuit 400 also includes scan enable (SE) inverter circuitry 403 configured identically to FIG. 3 to generate nse from scan enable (SE) and nm inverter circuitry 405 configured identically to generate m from node nm. Unless specifically described otherwise, the circuit elements, signals, and example operations of FIG. 4 are identical to those of FIG. 3.

In certain implementations, the circuit 400 differs from FIG. 3 through specific transistor rearrangements and an additional node merging, thereby optimizing circuit transistor count and CK load. For instance, in FIG. 4, clock signal CK input is positioned at the top-left side of master latch 405 rather than centrally, and the data input D is repositioned to the bottom of the input multiplexer transistor stack. This rearrangement is enabled because the slave latch 406 reduces two transistors from the feedback storage loop 464 as compared to the feedback storage loop 364 of FIG. 3. This simplification allows transistor node n1 to be advantageously merged (shared) as part of a circuit-sharing circuitry (e.g., along with the CK transistor of clock circuitry 410) between feedback storage loop 464 and the first NAND gate 420. Such sharing of node n1 is feasible because first NAND gate 420 is clock-gated, preventing contention during operation. Thus, advantageously, circuit 400 presents just four CK transistor loads to the clock distribution network.

Moreover, consistent with FIG. 3, the second NAND gate 430 and keeper sub-circuit 440 share a CK transistor at merged node n3, thereby enabling additional intra-flop CK sharing and transistor reduction. Further, in certain aspects, the first NAND gate 420 includes a latd-coupled transistor, as well as a combined PFET transistor (e.g., the integrated scan mux) coupled to node nm, an NFET transistor coupled to node m, along with the shared CK-coupled transistor 438. The keeper sub-circuit 440 is similarly structured and functions identically to FIG. 3, stabilizing node nm during CK and data transitions. Accordingly, circuit 400 maintains all operational advantages of circuit 300 described previously, while advantageously introducing an additional node merging at node n1, thus further optimizing transistor count and CK load. The simplification of the feedback storage loop 464, combined with intra-flop transistor merging, enhances the overall efficiency, power, performance, and area (PPA) characteristics of circuit 400, as compared to previously described implementations.

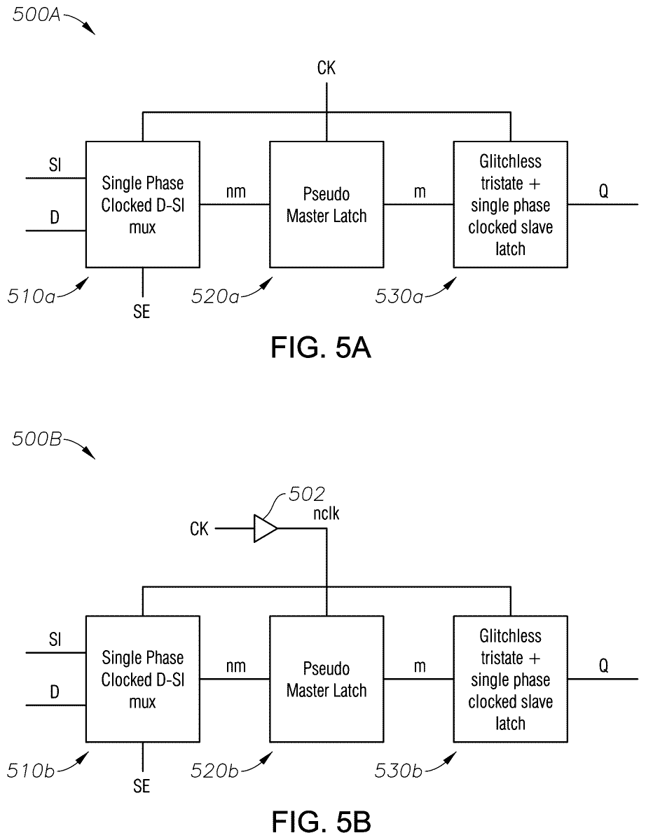

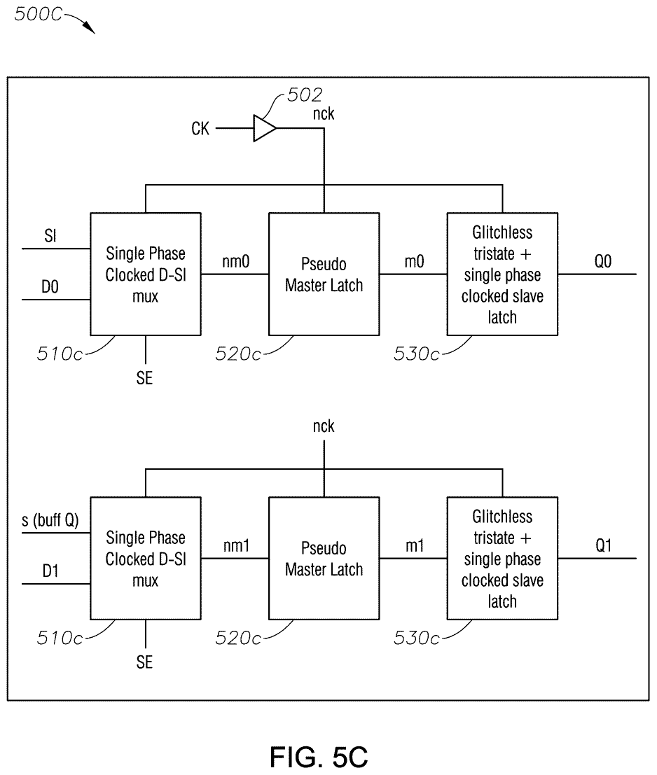

Referring to FIGS. 5A-5C, simplified functional block diagrams 500A-500C illustrating clock-sharing flip-flop circuit topologies are shown according to example implementations. In these implementations, the circuits are divided into functionally distinct blocks, each capable of independent operation, to clearly illustrate component interactions. In general, each implementation includes a single-phase clocked multiplexer (MUX), a pseudo-master latch (PML), and a glitchless tri-state inverter (e.g., tri-state write port) coupled with a single-phase clocked slave latch (GLTS+SPCKSL), consistent functionally (e.g., although circuit characterizations may differ) with previously described configurations of FIGS. 3 and 4.

FIG. 5A illustrates an example flip-flop circuit topology 500A including a single-phase clocked data-scan input multiplexer (e.g., single-phase clocked D-SI mux) 510, a pseudo-master latch (PML) 520, and a glitchless tri-state inverter coupled to a single-phase clocked slave latch (GLTS+SPCKSL) 530. In certain aspects, the single-phase clocked multiplexer 510 selects between a data input D and a scan input SI based on the scan enable signal SE, providing the selected input to the pseudo-master latch 520. The pseudo-master latch 520, configured using cross-coupled logic (e.g., NAND logic), latches the selected input data onto an internal node (e.g., node m). The latched data is subsequently transferred through a glitchless tri-state inverter into the single-phase clocked slave latch 530, resulting in data output Q. In the topology shown in FIG. 5A, all circuit blocks operate from a single-phase clock CK, with no inversion of the CK signal, thereby optimizing clock distribution and power efficiency.

FIG. 5B illustrates a “modified” flip-flop circuit topology 500B, similar to the circuit 500A described above. The circuit topology 500B, however, includes an inverter 502 coupled to clock CK, generating an inverted clock signal NCK (i.e., nclk). Although the overall clock distribution uses two phases (CK and NCK), each individual block within the circuit remains single-phase operated from NCK. Thus, while at the overall level circuit topology 500B uses two clock phases, internally each functional block remains single-phase operated. The single-phase clocked multiplexer 510a, the pseudo-master latch 520b, and the glitchless tri-state slave latch 530b, are consistent with the components and operations described with reference to FIG. 5A, but each is “de-morganized” (e.g., logic and transistor configurations reversed) to operate based on the inverted clock signal NCK rather than CK.

FIG. 5C illustrates a multi-bit flip-flop circuit topology 500C demonstrating how the single-phase flip-flop configuration can be efficiently scaled across multiple bits. The circuit topology 500C includes two or more bitcells (e.g., two shown for simplicity), each comprising the same blocks as described previously: a single-phase clocked multiplexer 510c, pseudo-master latch 520c, and glitchless tri-state inverter coupled to a single-phase clocked slave latch 530c. Advantageously, a single clock inverter 502 can generate the inverted clock NCK used simultaneously by multiple bitcells, thereby reducing overall clock loading and complexity. Each bitcell is inherently single-phase operated based on NCK, even though the circuit topology at the top level is driven by the two-phase signals CK and NCK. Although two bitcells are shown, circuit topology 500C is extendable to “N” bitcells, demonstrating scalability and efficiency in multi-bit configurations.

Thus, FIGS. 5A-5C collectively demonstrate versatile flip-flop circuit topologies employing intra-flop and inter-flop clock sharing strategies. These configurations optimize clock distribution and transistor count, significantly reducing clock loading and power consumption in both single-bit and multi-bit applications.

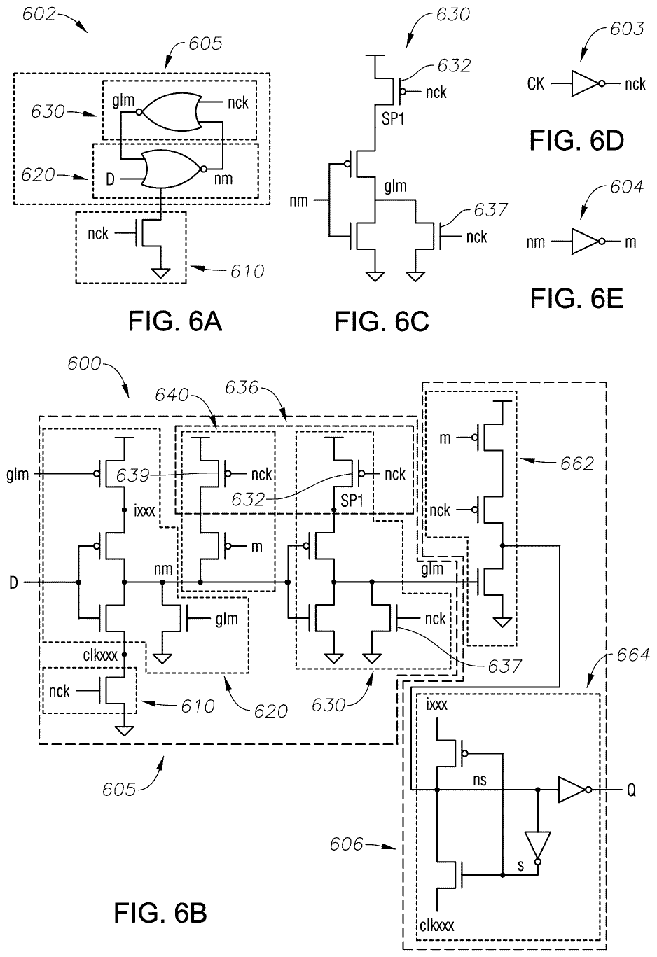

Referring to FIGS. 6A-6E, an example flip-flop circuit 600 employing a NOR-based configuration is illustrated according to example implementations. In certain aspects, NOR-based circuit 600 represents an equivalent De Morgan transformation of the NAND-based flip-flop implementations described previously (e.g., FIGS. 2A-2D). Specifically, circuit 600 employs inverted clock signaling NCK (i.e., nlck), which is generated by inverter circuitry (FIG. 6D) from an original clock signal CK. Accordingly, the circuit 600 provides pull-up transistor logic (e.g., PFET transistor 632 coupled to NCK), as opposed to pull-down transistor logic used in NAND-based implementations. Advantageously, this NOR-based flip-flop circuit 600 similarly incorporates a single-phase, low-power clock-sharing architecture, minimizing the number of clock-controlled transistors and ensuring stable data storage and propagation.

As illustrated, the circuit 600 includes a clock circuitry 610, a master latch 605 (e.g., a “pseudo” master latch), and a slave latch 606 (e.g., a “glitchless” slave latch). In certain examples, as shown, the master latch 605 includes a first logic structure 620 (e.g., a first NOR gate), a second logic structure 630 (e.g., a second NOR gate), and a keeper circuit 640. In certain cases, the slave latch 606 includes a glitchless tri-state inverter 662 (e.g., tri-state write port) and a feedback storage loop 664. Advantageously, the clock circuitry 610 generates a single-phase inverted clock signal NCK (derived from clock signal CK through inverter circuitry shown in FIG. 6D) to control data transitions throughout circuit 600 without additional buffering.

As depicted, FIG. 6A illustrates a circuit portion 602 shown as a logic block diagram. The circuit portion 602 includes clock circuitry 610 and master latch 605, where master latch 605 includes cross-coupled NOR gates comprising first logic structure 620 and second logic structure 630. In various implementations, as shown in FIG. 6B, the master latch 605 (e.g., pseudo-master latch: including first logic structure 620, second logic structure 630, and integrated keeper circuit 640) processes and stores incoming data before transferring it to the slave latch 606. The first logic structure 620 operates as a clock-gated NOR gate whose switching behavior is controlled by NCK. The second logic structure 630, also implemented as a NOR gate, is coupled to the output of the first logic structure 620 and interfaces with the keeper circuit 640, maintaining stability of internal nodes when NCK is inactive. Specifically, the keeper circuit 640 ensures node stability by holding a predefined logic state at node glm (e.g., a pre-discharged node), preventing unintended logic transitions.

As shown, with reference to FIG. 6C, a transistor-level implementation of the second logic structure 630 (e.g., second NOR gate) is highlighted. In certain implementations, a PFET transistor 632 at the top of the stack is configured for clock-sharing. For instance, in an intra-sharing example, shown in FIG. 6B, by merging node SP1 in keeper circuitry 640, distinct PFET devices (e.g., PFET 639, 632) of the keeper circuitry 640 and second logic structure 630 may be replaced with a single common clocked PFET transistor (e.g., shared clock-controlled (e.g., nclk-controlled) transistor at clock-sharing circuitry 636)). The PFET transistor 632, coupled to NCK, ensures node glm is reliably pre-discharged (set low) during the NCK active phase, enabling accurate logic transitions. Alternatively, in an inter-sharing example (not shown in FIGS. 6A-6E but explained in later implementations), the NCLK transistor 632 may be shared across multiple flip-flops, as a shared inter-clock head-transistor, allowing for the removal of redundant NCK-controlled transistors in multi-bit implementations.

FIG. 6D illustrates inverter circuitry configured to derive inverted clock NCK from clock CK, enabling NOR-based operation, consistent with previously described single-phase flip-flops. FIG. 6E illustrates inverter circuitry configured to derive the m signal from node nm, consistent with prior implementations.

Operationally, the circuit 600 parallels the previously described NAND-based flip-flop (FIGS. 2A-2D). For instance, during one operation, when inverted clock signal NCK is high (e.g., logic 1), the first NOR gate 620 enables data input D propagation into the master latch 605. Node glm is pre-discharged, ensuring correct logic-state transitions. When NCK transitions from high to low, data stored at node nm propagates to node glm through second NOR gate 630, accurately reflecting the input data. Subsequently, data stored at node glm transparently transfers through glitchless tri-state inverter 662 to slave latch 606, generating accurate output Q.

Accordingly, the circuit 600 demonstrates optimized single-phase NOR-based operation, significantly reducing transistor count, clock loading, and power dissipation. The NOR-based structure offers an advantageous alternative architecture supporting intra-flop and inter-flop clock (e.g., NCK) transistor sharing, preserving the functional and performance benefits of the NAND-based implementations described previously.

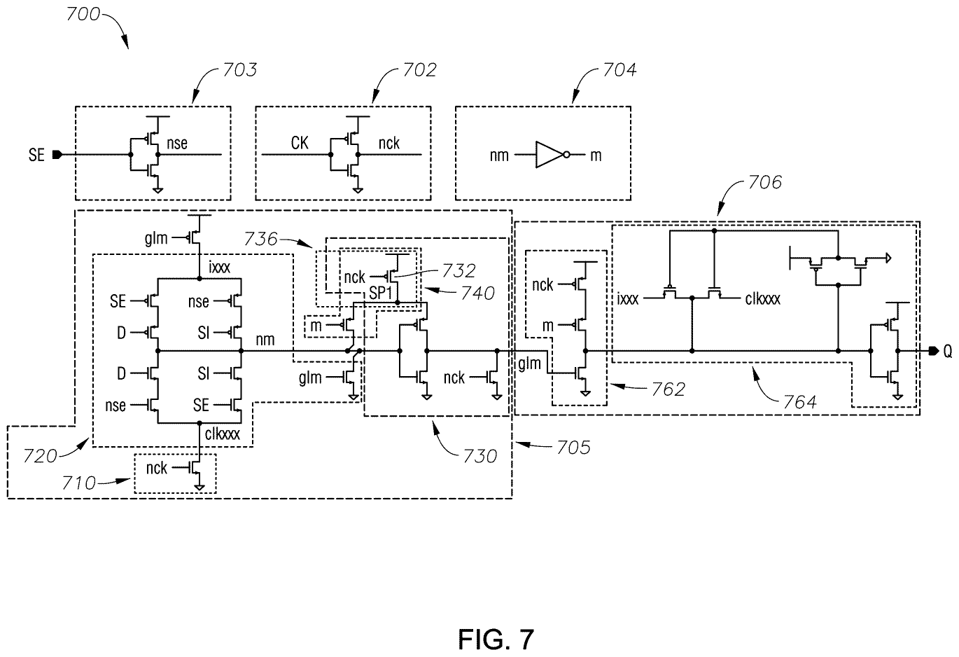

Referring to FIG. 7, an example flip-flop circuit 700 (e.g., NOR-based configuration) is illustrated according to example implementations. The circuit 700 represents the NOR-based equivalent (e.g., De Morgan transformation) of the NAND-based flip-flop described previously in FIG. 4. Accordingly, the circuit 700 shares many features, operations, and circuit elements substantially identical to those described above with reference to FIG. 4, except as specifically noted herein.

As illustrated, the circuit 700 includes clock circuitry 710, a master latch 705, and a slave latch 706, each functionally similar yet logically reversed (i.e., “demorganized”) compared to the corresponding structures of FIG. 4. For example, the clock circuitry 710 includes inverter circuitry configured to generate an inverted clock signal (NCK) from the original clock CK. In certain aspects, this inverted clock signal (NCK) allows single-phase internal operation while maintaining optimized edge rates locally within the circuit 700, without relying solely on the external clock distribution network. Advantageously, in various implementations, the inverter circuitry of the clock circuitry 710 can be localized to restore signal edge rates for NCK, thus enabling direct transistor drive within circuit 700 and improving the quality of internal signal transitions.

Similar to previously described implementations, in certain aspects, master latch 705 includes two cross-coupled logic structures: a first NOR gate (e.g., first logic structure) 720, and a second NOR gate (e.g., second logic structure) 730. In certain implementations, the first NOR gate 720 is similarly clock-gated, integrating an input multiplexer (e.g., scan mux), and is coupled to a keeper sub-circuit 740, which functionally corresponds to the keeper sub-circuit 640 described with reference to FIG. 6. The keeper sub-circuit 740 stabilizes node states, ensuring correct operation during NCK and data transitions. The slave latch 706 includes a glitchless tri-state inverter 762 (e.g., tri-state write port) and a feedback storage loop 764, configured consistently with the slave latch structures described previously.

Advantageously, the circuit 700 is characterized by specific transistor rearrangements and node merging, paralleling the advantageous optimizations described for FIG. 4. For instance, as depicted in FIG. 7, the inverter circuitry for clock NCK is positioned at the bottom-left portion of master latch 704, and data input (D) is similarly rearranged within the input multiplexer transistor stack, enabled by simplifications in slave latch 706 feedback storage loop 764 transistor count. This simplification allows transistor node merging similar to node n1 in FIG. 4, wherein certain circuit-sharing structures (e.g., NCK transistor sharing) between feedback storage loop 764 and first NOR gate 720 are realized. Such node sharing is feasible due to the first NOR gate 720 being clock-gated, thus eliminating potential contention during data propagation. Advantageously, the resulting circuit 700 presents just four NCK transistor loads to the clock distribution network. This minimized transistor load significantly eases drive requirements for the clock tree synthesis and improves the signal integrity and edge rates for clock signals delivered internally.

Moreover, consistent with prior examples, the circuit 700 employs a shared clock-controlled transistor (e.g., a shared transistor 732) at merged node SP1 common to the second NOR gate 730 and keeper sub-circuit 740, thereby enabling intra-flop NCK sharing and transistor-count optimization. The keeper sub-circuit 740 structure is functionally identical to that described in previous configurations, ensuring node stability during internal transitions and preserving stored data integrity.

Thus, the circuit 700 maintains all operational advantages previously described for NAND-based flip-flops (FIG. 4), while advantageously introducing a NOR-based configuration with localized inverted clock signal NCK. By incorporating intra-flop transistor sharing, node merging optimizations, and localized inverter circuitry for edge-rate improvement, the circuit 700 significantly enhances power, performance, and area (PPA) characteristics. The reduced NCK transistor load eases clock drive complexity, enabling robust flip-flop operation with substantially optimized transistor count, minimized clock loading, and enhanced signal integrity.

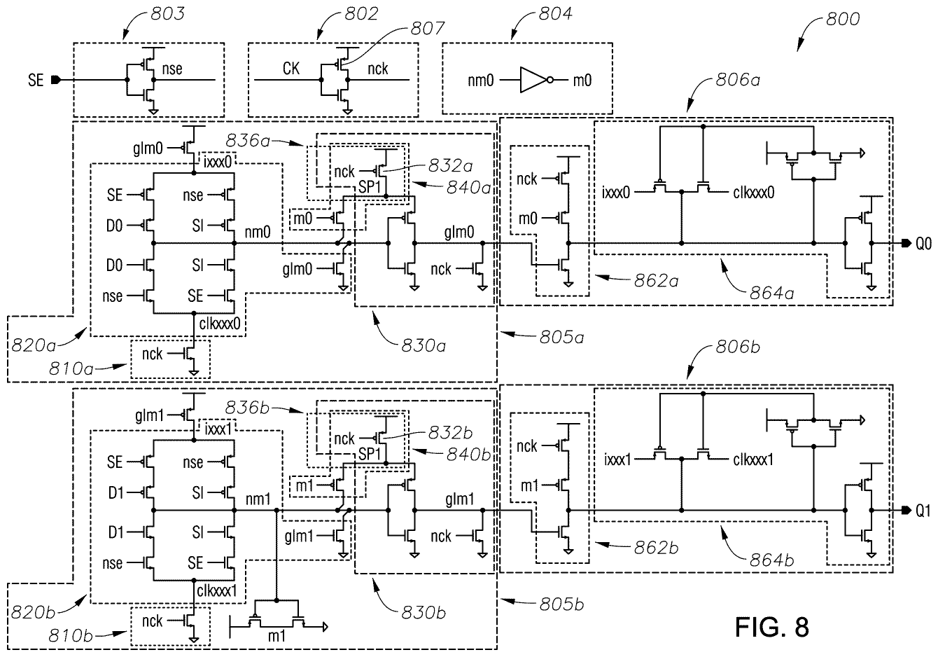

Referring to FIG. 8, an example flip-flop circuit 800 (e.g., a NOR-based multi-bit configuration) is illustrated according to example implementations. The circuit 800 advantageously demonstrates a multi-bit implementation wherein a single clock inverter within clock circuitry 810 is shared across multiple flip-flop bits (e.g., two bits shown for simplicity). In certain aspects, each flip-flop bit within the circuit 800 substantially corresponds to the single-bit flip-flop circuit 700 described previously with reference to FIG. 7, thus sharing substantially identical features, circuit elements, and operations unless explicitly described otherwise. To clearly differentiate identical elements between flip-flop bits, reference numerals corresponding to the first flip-flop bit are designated with the suffix “a” (e.g., master latch 805a, slave latch 806a), and those corresponding to the second flip-flop bit are designated with the suffix “b” (e.g., master latch 805b, slave latch 806b).

In certain implementations, as illustrated, for each bit, within the circuit 800 includes a respective master latch (805a, 805b), slave latch (806a, 806b), and associated circuitry structured identically to the single-bit implementation shown in FIG. 7. Specifically, each master latch (805a, 805b) includes cross-coupled NOR logic structures: a first NOR gate (820a, 820b) and a second NOR gate (830a, 830b), integrated with respective keeper sub-circuits (840a, 840b). Each slave latch (806a, 806b) similarly includes a glitchless tri-state inverter (862a, 862b) (e.g., tri-state write port) and a feedback storage loop (864a, 864b).

As depicted, the circuit 800 advantageously provides intra-flop clock transistor sharing within each bit. For example, the NOR structure (830a, 830b) includes an NCLK transistor (832a, 832b) configured similarly to transistor 732 of FIG. 7, providing internal node sharing (e.g., SP1 node) to reduce transistor count within each respective bit. However, notably, no interactivity or transistor sharing occurs between separate bits. Each flip-flop bit remains self-contained and functionally independent, with intra-flop sharing confined within each individual bit.

Advantageously, in the illustrated multi-bit configuration, a common clock inverter circuitry 802 generates an inverted clock signal NCLK from the primary clock input CK. This common inverter 807 distributes the single-phase NCLK signal simultaneously to each individual flip-flop bit. The single inverter 807 thus efficiently drives transistor gates within both bits (e.g., 805a, 806a and 805b, 806b), significantly reducing the load seen by the clock distribution network (CDN). Specifically, from the CDN perspective, the load reduces substantially to that of only one inverter rather than multiple clock transistor loads across multiple bits. Such an arrangement beneficially preserves clock signal integrity and edge rates, enhancing power, performance, and area (PPA) characteristics, particularly advantageous in high-density multi-bit flip-flop configurations.

Thus, circuit 800 demonstrates optimized multi-bit NOR-based single-phase flip-flop implementation, leveraging both intra-flop transistor sharing for transistor-count reduction and a shared single-phase inverter for efficient and robust multi-bit clock distribution. This configuration maintains all functional and performance advantages described for FIG. 7 while further optimizing clock load scalability and minimizing CDN complexity in multi-bit applications.

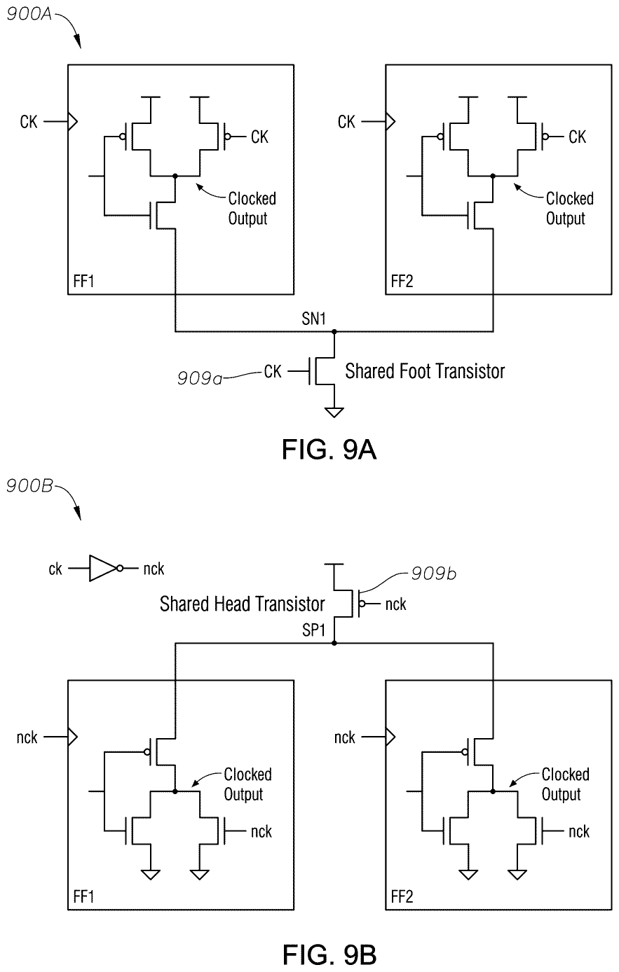

Referring to FIGS. 9A-9B, example flip-flop circuits 900A and 900B illustrate generalized principles of inter-flop clock transistor sharing according to example implementations. As illustrated, these circuits advantageously demonstrate how clock-controlled transistors may be shared across multiple flip-flops to minimize transistor count, clock loading, and power consumption. FIGS. 9A-9B differ from prior examples, which primarily focused on intra-flop sharing, by now providing inter-flop transistor sharing across multiple flip-flops.

In FIG. 9A, an example NAND-based flip-flop circuit configuration 900A is illustrated, demonstrating inter-flop sharing with a shared foot transistor. In certain implementations, the NAND-based flip-flop circuit (e.g., including flip-flops FF1 and FF2) utilizes a single-phase clock CK without requiring inversion. Conventionally, each NAND logic structure driving a clocked output node would typically include two CK-coupled transistors. Advantageously, as illustrated here, instead of each flip-flop independently providing these transistors, one transistor (an NFET transistor, in this example) is relocated to a “higher” hierarchical level outside the individual flip-flops. Thus, in such implementations, multiple flip-flops (e.g., FF1, FF2) may share a common clock-coupled NFET transistor, forming a shared foot transistor 909a. The sources of respective NFET transistors within each flip-flop are tied together and coupled as a shared node SN1 to the shared foot transistor 909a, substantially reducing the overall number of CK-coupled transistors. Consequently, as additional flip-flops are introduced, each incremental flip-flop does not require its own clock transistor, greatly reducing clock load and overall power dissipation.

In FIG. 9B, a NOR-based flip-flop circuit configuration 900B illustrates an equivalent De Morgan structure implementing inter-flop transistor sharing, here employing a shared head transistor. In certain implementations, the NOR-based flip-flop configuration similarly uses single-phase clocking but provides an inverted clock signal NCK, derived from clock CK via an inverter circuit 920. In this configuration, each flip-flop (e.g., FF1, FF2) includes a NOR-based logic structure with a PFET transistor at the top (“head transistor”) controlling the pre-discharging of a clocked output node. Conventionally, each flip-flop would independently provide a separate PFET transistor coupled to NCK. Advantageously, the illustrated implementation utilizes a shared head transistor 909b that is moved outside and shared across multiple flip-flops (FF1, FF2). Specifically, each NOR-based flip-flop has internal nodes coupled together (e.g., shared node SN1) and commonly connected to shared head transistor 930, effectively eliminating one PFET transistor per additional flip-flop. Thus, when NCK is low, the shared head transistor 930 allows internal output nodes to predischarge to logic 0, maintaining stable and accurate data propagation across multiple flip-flops.

FIGS. 9A-9B collectively illustrate a generalized inter-flop clock-sharing principle applicable to both NAND-and NOR-based configurations. In certain aspects, both configurations provide a clocked-output structure, either precharging (NAND) or pre-discharging (NOR) their respective output nodes based on the clock signals. As more flip-flops are integrated, redundant clock-controlled transistors (e.g., NFET in NAND configuration or PFET in NOR configuration) are advantageously removed, thereby significantly reducing clock load, transistor count, and power consumption. Importantly, the illustrated clock-sharing architectures are scalable across multiple flip-flop bits, ensuring robust performance, efficient clock distribution, and optimized transistor utilization in multi-bit designs.

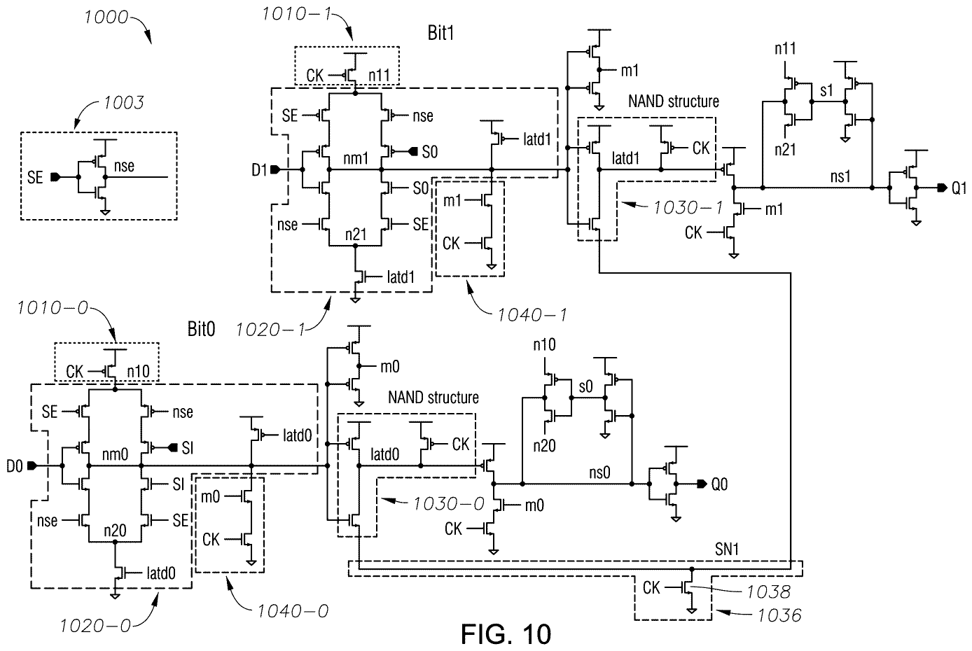

Referring to FIG. 10, an example flip-flop circuit 1000 is illustrated in a NAND-based multi-bit configuration, according to example implementations. The circuit 1000 extends the principles described previously in FIG. 4 by applying them advantageously across multiple bits (e.g., two bits shown for clarity). Specifically, for example, the circuit 1000 demonstrates inter-flop transistor sharing between multiple flip-flop bitcells, thereby significantly reducing transistor count, clock loading, and power dissipation compared to conventional multi-bit designs.

In certain implementations, the circuit 1000 includes two flip-flop bits—Bit 0 and Bit1 —each substantially identical to the single-bit flip-flop described previously with reference to FIG. 4. Accordingly, similar structures are labeled with matching reference numerals differentiated by the suffixes “0” (for Bit0) and “1” (for Bit1). Specifically, the first flip-flop bit (Bit0) comprises a master latch 1005-0, a slave latch 1006-0, a first NAND gate (e.g., first logic structure) 1020-0 (including an integrated scan mux), a second NAND gate (e.g., second logic structure) 1030-0, and a keeper sub-circuit 1040-0. Similarly, the second flip-flop bit (Bit1) comprises a master latch 1005-1, a slave latch 1006-1, a first NAND gate 1020-1 (including an integrated scan mux), a second NAND gate 1030-1, and a keeper sub-circuit 1040-1. The slave latches 1006-0, 1006-1 each similarly include respective glitchless tri-state inverters 1062-0, 1062-1 (e.g., tri-state write ports), and feedback storage loops 1064-0, 1064-1, identical to FIG. 4. In various aspects, for brevity, each detail of each individual flip-flop has not been duplicated but is structurally and functionally the same.

Advantageously, the circuit 1000 incorporates inter-flop sharing through a clock-sharing circuitry 1036 including shared clock-controlled transistor (e.g., shared foot transistor 1038), distinct from prior intra-flop examples. Conventionally, each NAND-based flip-flop would include an NFET transistor at the bottom of its logic stack coupled to a clock signal (CK). However, as depicted in FIG. 10, such redundant NFET transistors (previously at the bottom of the second NAND logic structures 1030-0, 1030-1) are advantageously removed from each flip-flop bit and replaced by a single common NFET transistor 1038 shared at the hierarchical top-level. Specifically, the two flip-flop bits (Bit0, Bit1) share a common node SN1 coupled to the shared foot transistor 1038, significantly reducing transistor count and clock load presented to the clock distribution network.

According to certain aspects, the circuit 1000 is specifically enabled by the internal architecture of the second NAND gates 1030-0, 1030-1, which incorporate precharging through PFET devices coupled to clock CK, along with bottom NFET devices (“foot transistors”) coupled to a low power supply potential (e.g., ground). Such a structure uniquely facilitates the sharing of the NFET foot transistor 1038 across multiple bits. Notably, however, in this inter-flop sharing arrangement, the clock-controlled NFET transistors within respective keeper sub-circuits 1040-0, 1040-1 remain separate and are not shared at the SN1 node. Consequently, keeper sub-circuit clock transistors cannot be simultaneously shared when the inter-flop clock transistor sharing is implemented at SN1. In certain implementations, the scan multiplexer circuitry is integrated directly within the first NAND logic structures 1020-0, 1020-1. Specifically, the PFET transistor with a gate coupled to signal latd (e.g., latd0 for Bit0 and latd1 for Bit1) forms an integral part of each first NAND gate 1020-0, 1020-1, and is not separately provided. Hence, the first NAND logic structures advantageously integrate both the scan multiplexers and latd-controlled transistors to simplify overall transistor arrangement.

Accordingly, FIG. 10 demonstrates a novel, multi-bit, inter-flop NAND-based flip-flop configuration. By implementing shared clock-controlled transistor 1038 at node SN1, circuit 1000 substantially reduces transistor count and significantly eases clock distribution network loading. The illustrated multi-bit arrangement retains all operational and performance benefits of previously described single-bit configurations, while advantageously scaling to multiple bits through efficient inter-flop transistor sharing strategies.

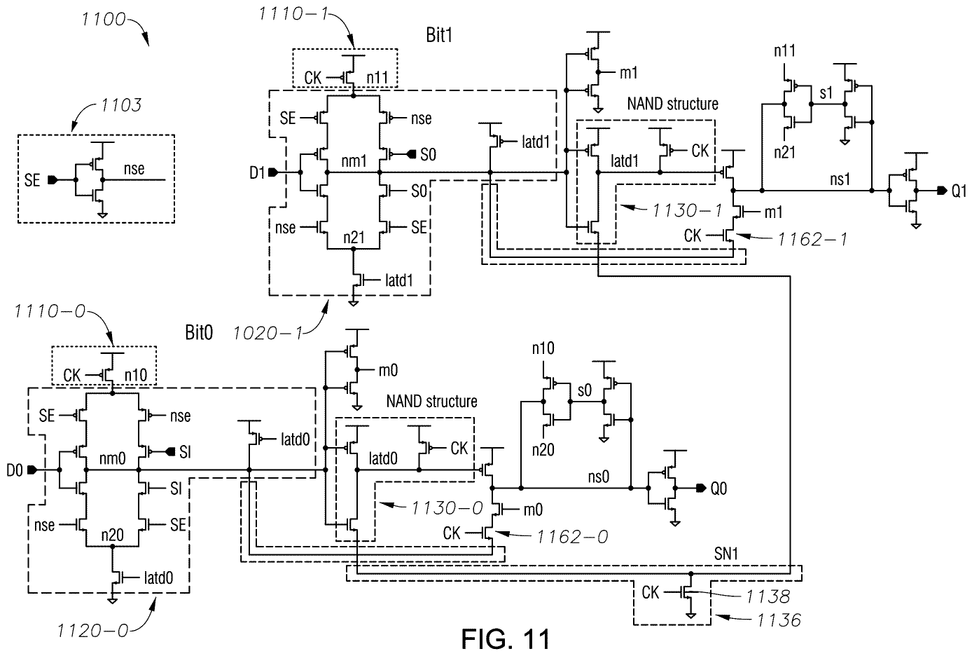

Referring to FIG. 11, an example multi-bit NAND-based flip-flop circuit 1100 is shown, according to example implementations. The circuit 1100 substantially corresponds to the multi-bit flip-flop circuit 1000 described previously with reference to FIG. 10 and similarly includes two example flip-flop bitcells (Bit0, Bit1). For instance, each bitcell includes respective master latches (1105-0, 1105-1), slave latches (1106-0, 1106-1), first NAND logic structures (1120-0, 1120-1) integrating scan multiplexers, and second NAND logic structures (1130-0, 1130-1), configured analogously to FIG. 10. Each bitcell also maintains identical glitchless tri-state inverter circuitry (1162-0, 1162-1) (e.g., tri-state write ports) and feedback storage loops (1164-0, 1164-1) within respective slave latches.

Advantageously, in certain implementations, circuit 1100 differs from FIG. 10 by introducing an additional optimization: the removal of separate keeper sub-circuits (previously keeper sub-circuits 1040-0, 1040-1 in FIG. 10). In this optimized embodiment, the functionality previously provided by the keeper sub-circuit(s) is advantageously merged directly into respective glitchless tri-state inverters (1162-0, 1162-1) (e.g., tri-state write ports). Specifically, keeper sub-circuit elements are integrated with the tri-state inverter transistors, eliminating redundant transistor structures and further enhancing transistor count and power efficiency.

Similar to FIG. 10, the circuit 1100 maintains both intra-flop and inter-flop transistor sharing within each bitcell. In particular, intra-flop transistor sharing occurs at merged internal nodes (e.g., node n10 in Bit0 and node n11 in Bit1). As in prior examples, node n10 of master latch 1105-0 is shared with slave latch 1106-0, and similarly, node n11 of master latch 1105-1 is shared with slave latch 1106-1. These merged nodes effectively enable transistor sharing within each flip-flop bitcell, thereby minimizing internal transistor count and clock loading.

Additionally, the circuit 1100 continues to incorporate inter-flop clock transistor sharing by including clock-sharing circuitry 1136 comprising a shared clock-controlled transistor (e.g., shared foot transistor 1138) coupled at common node SN1, positioned at the hierarchical top-level of the multi-bit structure. Consistent with FIG. 10, the redundant NFET foot transistors traditionally provided at the bottom of each NAND-based flip-flop bitcell are removed. Instead, these flip-flop bitcells (Bit0, Bit1) share the common NFET foot transistor 1138 at node SN1. Such transistor sharing significantly reduces the transistor count and the clock load observed by the clock distribution network (CDN).

Thus, FIG. 11 illustrates a further optimized multi-bit NAND-based flip-flop configuration employing both intra-flop transistor sharing at nodes n10, n11 and inter-flop transistor sharing at shared node SN1. Advantageously, this second embodiment further removes redundant keeper sub-circuits by merging their functionality directly into the tri-state drivers within each slave latch. Consequently, the circuit 1100 achieves enhanced power, performance, and area (PPA) efficiency through reduced transistor count, minimized clock loading, and improved scalability for multi-bit flip-flop applications.

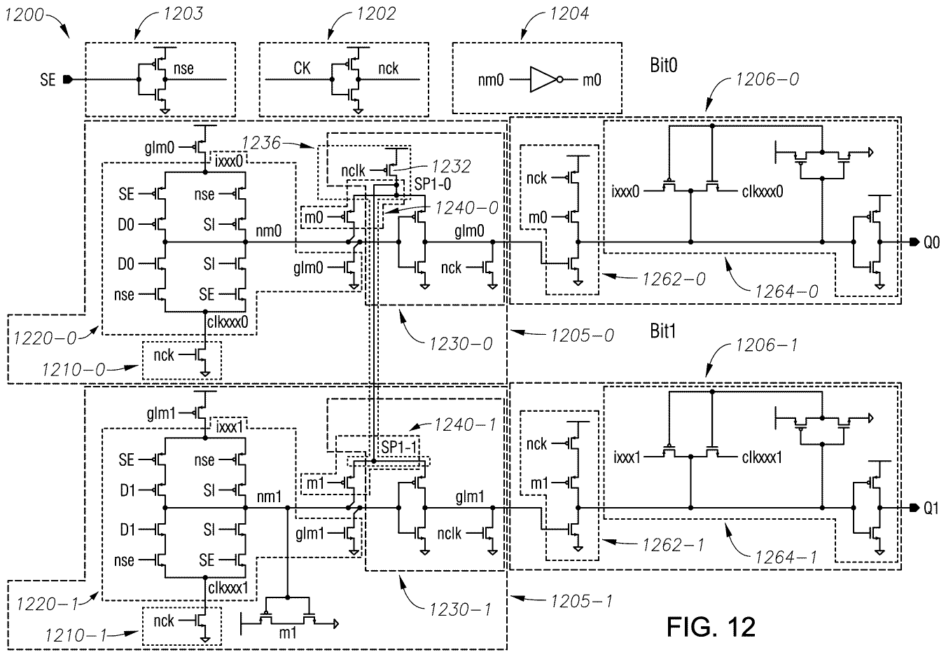

Referring to FIG. 12, an example flip-flop circuit 1200 (e.g., NOR-based multi-bit configuration) is illustrated according to example implementations. The circuit 1200 advantageously demonstrates inter-flop transistor sharing principles similar to those described with reference to FIG. 8 (NAND-based), but now applied to a NOR-based flip-flop structure. In certain implementations, the circuit 1200 includes two flip-flop bitcells (e.g., two shown labeled Bit0 and Bit1 for simplicity), each substantially identical to the single-bit NOR-based flip-flop described previously with reference to FIG. 7. Corresponding structures within each bitcell are indicated by consistent reference numerals differentiated by suffixes “-0” (Bit0) and “-1” (Bit1). For example, master latch 1205-0 and slave latch 1206-0 form Bit0, while master latch 1205-1 and slave latch 1206-1 form Bit1.

In certain implementations, each flip-flop bitcell within the circuit 1200 includes a master latch (1205-0, 1205-1) with cross-coupled NOR logic structures: a first NOR gate (1220-0, 1220-1) and a second NOR gate (1230-0, 1230-1) coupled respectively to integrated keeper sub-circuits (1240-0, 1240-1). Each slave latch (1206-0, 1206-1) similarly includes glitchless tri-state inverters (1262-0, 1262-1) (e.g., tri-state write ports) and feedback storage loops (1264-0, 1264-1), identical in structure and function to those described in previous single-bit implementations (e.g., FIG. 7).

The circuit 1200 specifically illustrates inter-flop transistor sharing in a NOR-based architecture through the inclusion of clock-sharing circuitry 1236. As illustrated, rather than each NOR logic structure within individual bits having a separate top-level PFET transistor (e.g., head transistor coupled to inverted clock NCK), a common head transistor 1232 is advantageously shared across multiple flip-flop bits. Thus, each additional flip-flop bit added to the configuration no longer requires a separate dedicated PFET transistor, significantly reducing overall transistor count and NCLK load on the clock distribution network (CDN). Specifically, each NOR structure (e.g., second NOR gates 1230-0, 1230-1) includes internal nodes (e.g., nodes SP1-0 and SP1-1), which are advantageously merged together and coupled directly to the shared head transistor 1232. Such elements combined include portions of the clock-sharing circuitry 1236. Consequently, the shared head transistor 1232 is coupled to a high supply potential (e.g., VDD), allowing pre-discharging operations to reliably occur during NCLK transitions across multiple flip-flop bitcells simultaneously.

In certain implementations, this NOR-based multi-bit inter-flop sharing structure substantially parallels the NAND-based structure of FIG. 10, but with transistor polarities and coupling reversed (e.g., DeMorgan-transformed). In contrast to the NAND-based implementation where a shared foot transistor is coupled to ground, here, the shared head transistor 1232 is coupled to VDD, functioning as a pre-discharge transistor for the NOR-based flip-flops. In various aspects, this topology effectively reduces transistor count by eliminating redundant NCLK-controlled PFET devices from each flip-flop bit, significantly lowering transistor load observed by the clock distribution network (CDN). Such transistor-sharing optimizations improve power efficiency, reduce the complexity of the CDN, and enhance clock-signal integrity, especially beneficial for high-density, multi-bit flip-flop applications.

Thus, the circuit 1200 demonstrates advantageous inter-flop transistor sharing and scalability in a NOR-based single-phase flip-flop configuration. This configuration maintains all operational and performance benefits previously described for NAND-based implementations (e.g., FIG. 10 and FIG. 11), while providing further optimization through node merging and shared head transistor strategies that significantly reduce transistor count, minimize clock loading, and improve the overall PPA characteristics for multi-bit flip-flop designs.

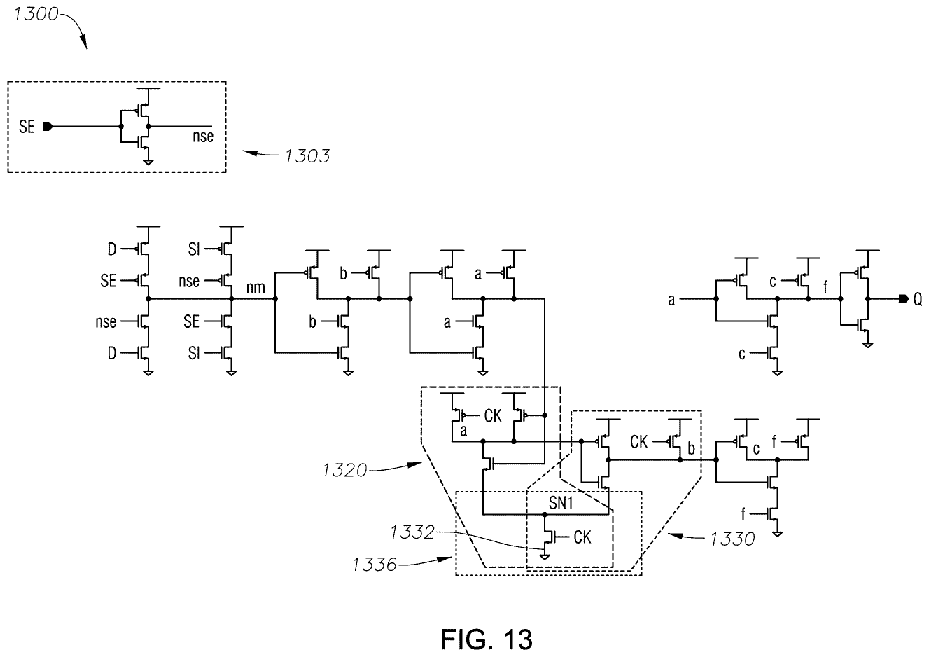

Referring to FIG. 13, an example flip-flop circuit 1300 illustrating an alternative secondary single-phase NAND-based topology is shown according to example implementations. In certain aspects, circuit 1300 advantageously employs intra-flop transistor sharing via clock-sharing circuitry 1336, which includes a common node SN1 and shared clock-coupled NFET transistor 1336. Although circuit 1300 shares certain structural and operational characteristics with previously described NAND-based flip-flops (e.g., FIGS. 4, 10, and 11), the depicted topology represents a distinct secondary configuration optimized for transistor sharing.

Specifically, the example circuit 1300 includes two cross-coupled NAND gates (1320, 1330), each coupled to single-phase clock signal CK. Advantageously, these NAND gates (1320, 1330) are intra-merged at shared node SN1, enabling them to utilize a single NFET transistor (shared foot transistor 1332). Such circuitry corresponds to an example clock-sharing circuit 1336. By merging at node SN1, the need for redundant CK-coupled NFET transistors at the bottom of each NAND gate stack is eliminated, significantly reducing transistor count, clock loading, and circuit complexity.

Consequently, the example circuit 1300 advantageously presents only three CK transistor loads to the clock distribution network (CDN). This reduced CK load enhances clock signal edge rates, decreases power consumption, and improves signal integrity during data propagation. Thus, the illustrated NAND-based architecture achieves optimized intra-flop transistor sharing, maintaining latch stability, data accuracy, and glitchless operation consistent with prior implementations, while further enhancing power, performance, and area (PPA) efficiency.

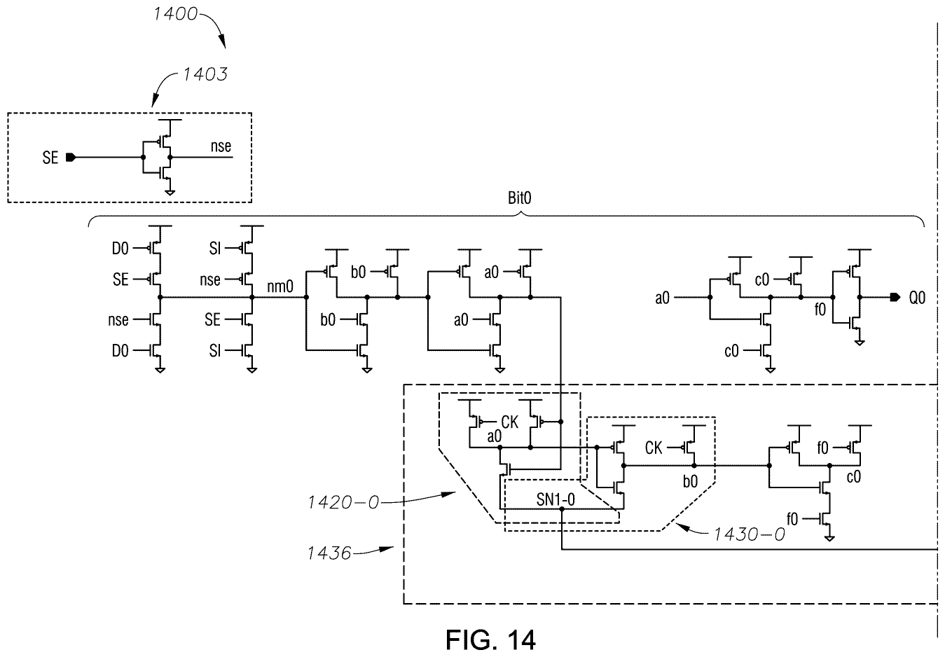

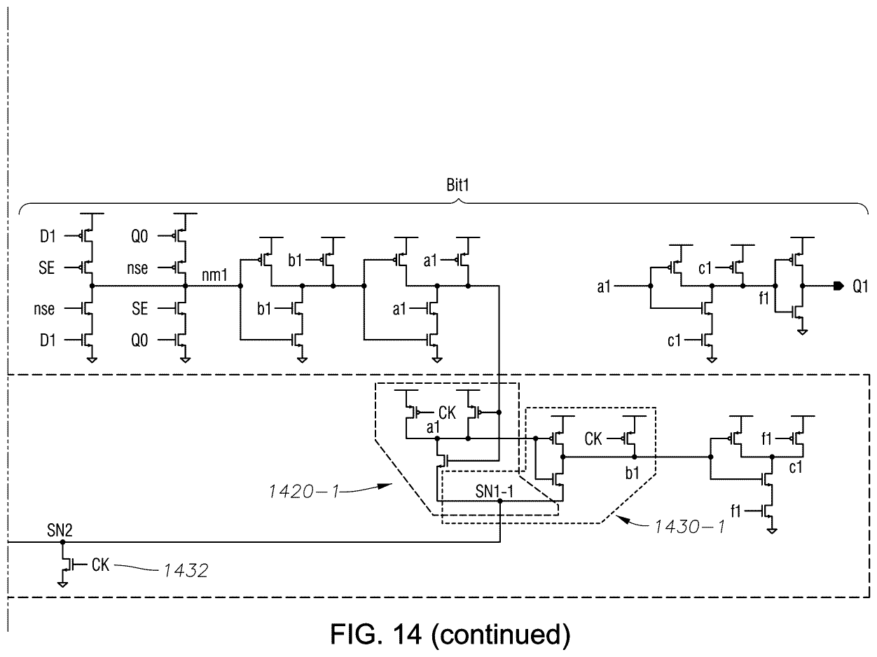

Referring to FIG. 14, an example multi-bit flip-flop circuit 1400 is illustrated according to example implementations. Specifically, the circuit 1400 illustrates how multiple bitcells (e.g., two shown: Bit0 and Bit1) may be advantageously combined to achieve both intra-flop and inter-flop transistor sharing. In certain aspects, each bitcell (Bit0, Bit1) substantially corresponds to the single-bit flip-flop 1300 described with reference to FIG. 13, including cross-coupled NAND logic structures (1420-0, 1430-0 in Bit0; 1420-1, 1430-1 in Bit1).

Advantageously, the illustrated configuration implements both intra-flop and inter-flop transistor sharing. Within each bitcell, two cross-coupled NAND gates (1420-0 and 1430-0 in Bit0, 1420-1 and 1430-1 in Bit1) have merged internal nodes (SN1-0, SN1-1), enabling intra-flop sharing of a CK-coupled NFET transistor 1432 (e.g., shared foot transistor). Additionally, the circuit 1400 further implements inter-flop transistor sharing by combining nodes (e.g., shared node SN2, which is the same as SN1-0, SN-1) across separate bitcells, allowing the same single CK-coupled NFET transistor 1432 (e.g., foot transistor) to be shared among multiple bitcells. Specifically, redundant CK-coupled NFET devices at the bottom of each NAND structure pull-down stack are replaced by a common external NFET transistor 1432 coupled to the CK signal, substantially reducing transistor count. As may be appreciated, all of this shared circuitry collectively would comprise the clock-sharing circuitry 1436.

In the depicted example, each NAND structure inherently includes a CK-coupled PFET transistor to precharge the respective output nodes, while the bottom-most CK-coupled NFET transistor acts as the pull-down foot transistor. This arrangement uniquely facilitates both intra-flop and inter-flop sharing, significantly optimizing transistor count. For instance, the circuit 1400 advantageously presents only five transistor loads (e.g., a (2N+1) transistor load, where N=number of flip-flop bits) to the clock distribution network (CDN), compared to six transistor loads in conventional two-bit configurations. This combined intra-flop and inter-flop transistor-sharing strategy significantly improves power, performance, and area (PPA) efficiency, providing the lowest transistor so far encountered among described the examples.

Accordingly, the illustrated circuit 1400 advantageously demonstrates optimized multi-bit scalability by effectively reducing CK transistor loading through strategic node merging and shared CK-coupled transistor circuitry. By eliminating redundant clock-coupled transistors across and within multiple bitcells, the circuit 1400 achieves significant transistor-count reduction, minimized CDN complexity, and improved signal integrity, power dissipation, and overall circuit performance in multi-bit flip-flop implementations.

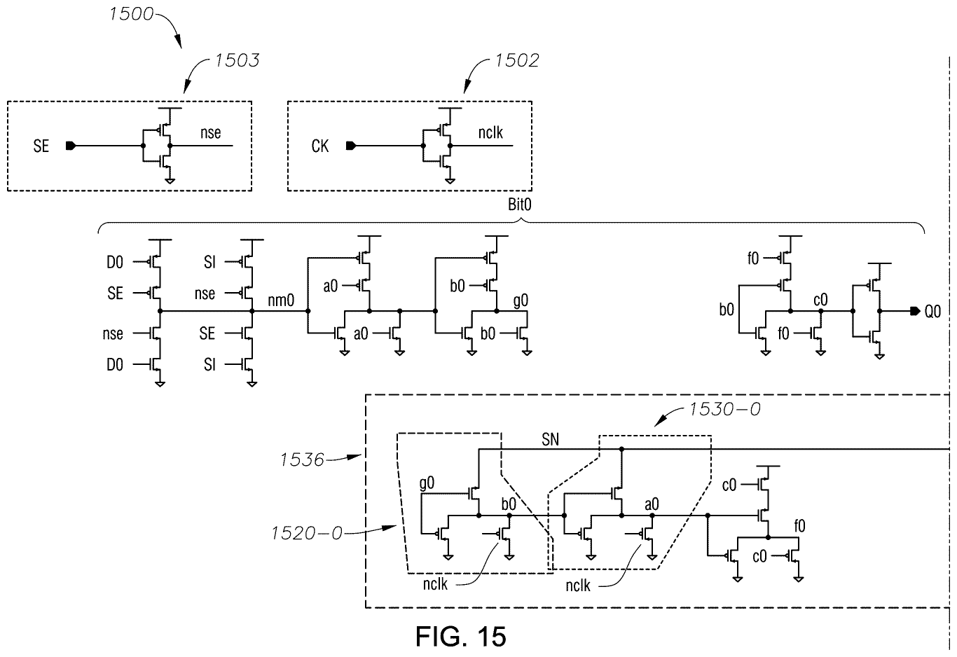

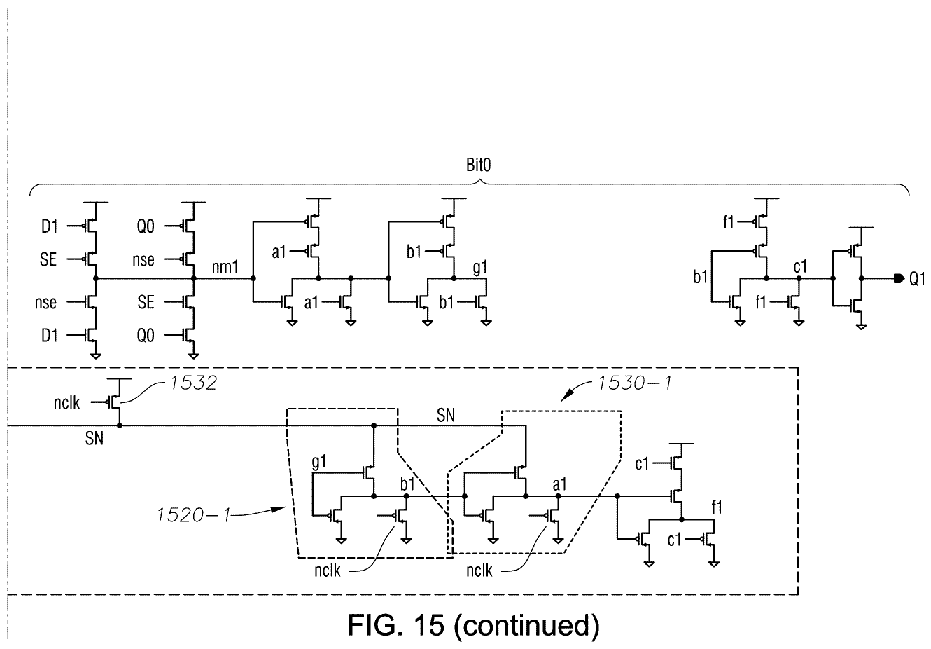

Referring to FIG. 15, an example multi-bit flip-flop circuit 1500 (e.g., NOR-based configuration with inverted clock NCLK) is illustrated according to example implementations. Specifically, the circuit 1500 advantageously demonstrates how multiple bitcells (e.g., two bitcells shown: Bit0 and Bit1) may be combined to implement both intra-flop and inter-flop transistor sharing within a NOR-based architecture. In certain aspects, each bitcell (Bit0, Bit1) substantially corresponds to the single-bit NOR-based flip-flop described previously with reference to FIG. 12, including respective cross-coupled NOR logic structures (1520-0, 1530-0 in Bit0; 1520-1, 1530-1 in Bit1).

Advantageously, the illustrated configuration implements both intra-flop and inter-flop transistor sharing. Within each bitcell, two cross-coupled NOR gates (1520-0 and 1530-0 in Bit0, 1520-1 and 1530-1 in Bit1) have merged internal nodes (e.g., SP1-0, SP1-1), enabling intra-flop sharing of respective NCLK-coupled PFET transistors (head transistors). Additionally, the circuit 1500 further implements inter-flop transistor sharing by combining nodes (e.g., shared node SP21) across separate bitcells, allowing a single shared PFET transistor 1532 (e.g., common head transistor) to be coupled externally and shared among multiple bitcells. Specifically, redundant NCLK-coupled PFET devices at the top of each NOR structure transistor stack are replaced by the shared external PFET transistor 1532 coupled to the inverted clock signal NCLK, substantially reducing transistor count. All such circuitry combined comprises clock-sharing circuitry 1536.

In the illustrated example, each NOR structure inherently includes an NCLK-coupled NFET transistor that pre-discharges respective output nodes, while the top-most NCLK-coupled PFET transistor (head transistor) is coupled to a high supply potential (e.g., VDD). This arrangement uniquely facilitates both intra-flop and inter-flop transistor sharing, significantly optimizing transistor count. For instance, the circuit 1500 advantageously presents only two CK transistor loads and maintains five transistor loads on the inverted clock NCLK network due to the shared PFET transistor. Specifically, the circuit 1500 thus achieves a substantially reduced transistor load presented to the clock distribution network (CDN) compared to conventional configurations, significantly improving power, performance, and area (PPA) efficiency.

Accordingly, the illustrated circuit 1500 advantageously demonstrates optimized multi-bit scalability in a NOR-based configuration by effectively reducing transistor loading on both CK and NCLK signals through strategic node merging and shared transistor circuitry. By eliminating redundant NCLK-coupled PFET transistors across and within multiple bitcells, the circuit 1500 achieves significant transistor-count reduction, minimized CDN complexity, and improved signal integrity, power dissipation, and overall circuit performance in multi-bit flip-flop implementations.

In various implementations, as described with reference to FIGS. 1-15, NCK and NLCK have been used interchangeably as the inverted clock signal. Moreover, for example, the clock-coupled transistors correspond to clock-controlled transistors The clock-sharing circuitry as described herein includes each of the embodiments having clock-related sharing circuit elements. For instance, dashed lines in the illustrative drawings are not intended to be limiting of the circuit sharing circuitry but just to depict certain shared elements. Hence, the circuit-sharing circuitry includes all of the circuit elements and nodes in each of the respective implementations of FIGS. 1-15.

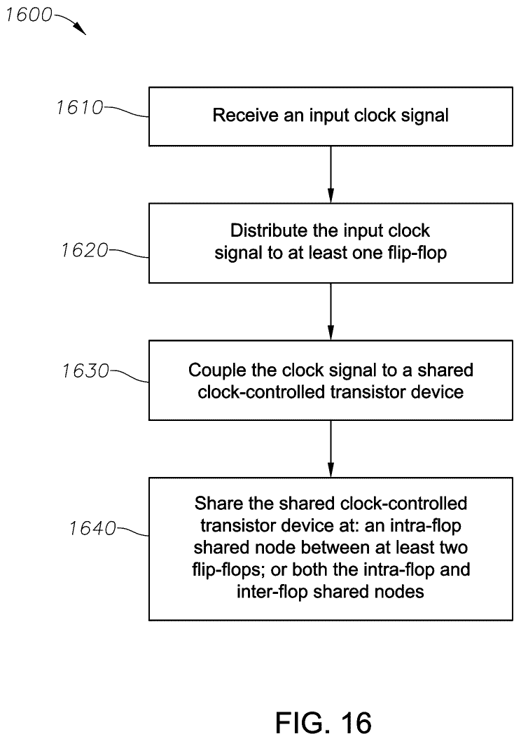

Referring to FIG. 16, a flowchart illustrating an example operational method 1600 (i.e., procedure) for implementing clock-sharing in flip-flop circuits is shown according to example implementations. Advantageously, in various aspects, method 1600 provides efficient transistor utilization and reduced clock network loading by strategically employing intra-flop transistor sharing within individual flip-flops, inter-flop transistor sharing across multiple flip-flops, or a combination thereof.

At block 1610, the method 1600 includes receiving an input clock signal. For instance, with reference to various implementations described previously (e.g., FIGS. 1-15), an input clock signal (CK or inverted clock signal NCK) is generated or received by clock circuitry (e.g., as certain examples, clock circuitry 310 of FIG. 3, clock circuitry 610 of FIG. 6, or clock circuitry 710 of FIG. 7, among others as described herein). The clock circuitry generates either a single-phase original clock signal CK, or alternatively, an inverted clock signal NCK derived from CK via localized inverter circuitry, depending on the chosen NAND-or NOR-based configuration, respectively.

At block 1620, method 1600 includes distributing the received clock signal to one or more flip-flops via one or more clock-controlled transistor devices. In certain implementations, for example, the clock-controlled transistor device comprises a transistor positioned either as a foot transistor at the bottom-most transistor stack position of NAND-based logic structures (e.g., shared foot transistor 1038 in FIG. 10 or transistor 1432 in FIG. 14), or as a head transistor at the top-most transistor stack position of NOR-based logic structures (e.g., shared head transistor 1232 in FIG. 12 or transistor 1232 in FIG. 12).

At block 1630, method 1600 includes distributing the clock signal by coupling the clock signal to one or more clock-controlled transistor devices. For instance, as described in FIGS. 10 and 11, in NAND-based configurations, a single-phase CK signal is distributed to a shared foot transistor (e.g., transistor 1038 or 1138), while in NOR-based configurations, as described in FIGS. 12 and 15, an inverted clock signal NCK is coupled to a shared head transistor (e.g., transistor 1232 in FIG. 12 or FIG. 15).

At block 1640, the method further comprises distributing the clock signal by sharing the clock-controlled transistor device at one or more shared nodes. In certain aspects, this sharing includes intra-flop sharing, inter-flop sharing, or both intra-flop and inter-flop transistor sharing. In the intra-flop sharing example, as illustrated in FIGS. 3-4 and 13, multiple internal logic structures within the same flip-flop are advantageously coupled at a shared node (e.g., SN1), enabling the removal of redundant clock-controlled transistors by replacing them with a single shared transistor. In inter-flop sharing examples, as illustrated in FIGS. 10-12 and 14-15, multiple flip-flops share a common transistor device at a shared node (e.g., SN1), positioned hierarchically above multiple flip-flop bitcells. For instance, as illustrated in FIG. 14 (NAND-based), multiple flip-flop bitcells share a common foot transistor at node SN1, significantly reducing the number of CK-driven transistors. Similarly, as illustrated in FIG. 15 (e.g., NOR-based), multiple flip-flop bitcells share a common head transistor at node SP1 coupled to an inverted clock signal NCK, significantly reducing redundant transistor loading and power dissipation across multiple bitcells.

In certain aspects, the logic structures comprise cross-coupled NAND gates, and sharing comprises coupling the shared clock-controlled transistor device at a bottom-most transistor stack position of the NAND logic structures. In some aspects, sharing the shared clock-controlled transistor device comprises positioning the shared transistor as a shared foot transistor coupled to a low power supply node. In some cases, sharing the shared clock-controlled transistor device comprises positioning the shared transistor as a shared head transistor coupled to a high power supply node.

In various cases, generating an inverted clock signal from the clock signal using localized inverter circuitry; and simultaneously coupling the inverted clock signal to multiple flip-flops. In certain aspects, each flip-flop comprises cross-coupled NAND gates or cross-coupled NOR gates configured to precharge or predischarge internal nodes in response to the clock signal.

In some implementations, the method 1600 further includes: integrating an input multiplexer into a first logic structure of a master latch of the flip-flop; and coupling the first logic structure to a keeper circuit configured to maintain stability of a clocked node within the master latch. In certain cases, the method 1600 further includes: coupling an output node of a master latch to a tri-state inverter in a slave latch of the flip-flop, wherein the tri-state inverter integrates keeper circuitry configured to maintain node stability without requiring a separate keeper transistor.

In some aspects, coupling the clock signal includes: generating an inverted clock signal through clock inverter circuitry, and providing the inverted clock signal simultaneously to two or more flip-flops in a multi-bit configuration. In certain cases, the shared clock-controlled transistor device is positioned: at a bottom-most transistor stack position in a NAND-based logic structure; or at a top-most transistor position in a NOR-based logic structure.

Accordingly, the method 1600 advantageously facilitates flexible yet robust clock-sharing strategies in flip-flop circuits. By strategically implementing intra-flop transistor sharing within individual flip-flops, inter-flop transistor sharing across multiple flip-flops, or simultaneous application of both sharing techniques, the method achieves significant reductions in transistor count, clock load complexity, power dissipation, and improved overall circuit performance and scalability.

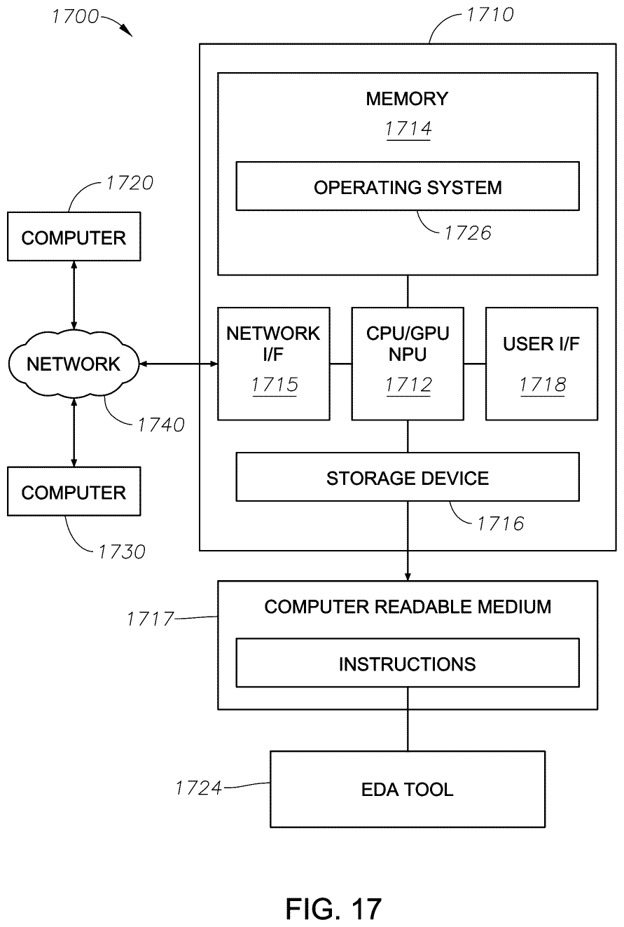

Also, according to other aspects of the operational methods, an output may be generated based on the operational dispositions. For example, with reference to various implementations as described in FIGS. 1-15, an output (i.e., a circuit design) (e.g., a memory architecture, multi-threshold offerings for memory compilers) may be generated based on various circuit element positionings. In some implementations, an EDA tool 1724 (as described with reference to FIG. 17) may allow users to input certain values, and generate a specific circuit design.

Referring to FIG. 17, a block diagram of an example computing system 1700 configured to implement and facilitate clock-sharing flip-flop circuit configurations, according to example implementations. Specifically, the computing system 1700 advantageously employs electronic design automation (EDA) tools configured to synthesize, simulate, verify, and optimize transistor-sharing techniques (e.g., intra-flop and inter-flop clock transistor sharing) described previously with reference to FIGS. 1-16. In certain implementations, the computing system 1700 executes automated processes that enable transistor-level optimizations, transistor node merging, and reduced clock transistor loading within flip-flop designs, thereby achieving significantly improved power, performance, and area (PPA) characteristics.

As illustrated, the computing system 1700 comprises a processing system 1710 including one or more processors 1712 (e.g., CPU, GPU, or NPU), memory 1714, and a storage device 1716. In various implementations, the processors 1712 execute EDA tool software 1724 stored within memory 1714 or other storage device(s) 1716. The memory 1714 represents any suitable volatile or non-volatile storage medium such as random-access memory (RAM), cache, or flash memory configured to store instructions and data utilized by the processors 1712. Additionally, computing system 1700 includes input/output (I/O) interface circuitry 1718 enabling interactions with external devices and peripherals, including input devices (e.g., keyboard, mouse), output devices (e.g., displays), and storage devices 1722 (e.g., hard drives, solid-state drives, cloud storage). Moreover, a network interface 1716 enables communication with external networks 1740, facilitating distributed or cloud-based EDA tool operation.

In certain implementations, as depicted, the computing system 1700 executes an EDA tool 1724 configured to automatically facilitate transistor-level synthesis, logic-level optimization, schematic capture, layout generation, and circuit verification, specifically directed towards flip-flop circuits employing transistor sharing techniques described herein (e.g., FIGS. 1-16). For instance, the EDA tool 1724 advantageously automates identification and integration of clock-sharing circuitry structures (e.g., structures comprising shared foot or head transistors, intra-flop and inter-flop transistor sharing at merged nodes, etc.) into schematic and layout designs. Specifically, the EDA tool 1724 may automatically recognize and exploit opportunities for intra-flop transistor sharing (e.g., node SN1 within a single flip-flop), inter-flop transistor sharing (e.g., common transistor shared across multiple flip-flops), or a combination of both techniques.

In certain implementations, the EDA tool 1724 automatically generates optimized transistor-level configurations for NAND-based and NOR-based flip-flop topologies. In particular, for NAND-based flip-flop implementations, the EDA tool 1724 advantageously identifies topologies enabling the use of a shared foot transistor coupled to a low power supply (e.g., ground), where the shared foot transistor can be utilized across multiple flip-flops to minimize transistor redundancy. Alternatively, in NOR-based implementations, the EDA tool 1724 facilitates the identification of opportunities for transistor sharing using a common head transistor coupled to a high power supply (e.g., VDD). By automating these identification and optimization tasks, the EDA tool 1724 substantially reduces design complexity and transistor count, greatly improving overall circuit efficiency.

Moreover, the computing system 1700 enables multi-bit scalability by employing automated clock inverter circuitry configured to generate inverted clock signals (NCK) that may be simultaneously coupled to multiple flip-flops. Such configurations reduce the load presented to the clock distribution network (CDN) and maintain high-quality clock edge rates. The EDA tool 1724 thus advantageously automates the insertion, optimization, and verification of localized inverter circuitry within flip-flop clusters to facilitate efficient multi-bit clock sharing. As further shown, the computing system 1700 can operate within a networked environment, communicating via one or more networks 1740 with additional computing systems (e.g., cloud-based or distributed processing systems). Such distributed processing configurations may further enhance computational efficiency, allowing parallelized circuit optimization, accelerated simulation, verification processes, and rapid design iteration cycles.

In example implementations, circuit-related diagrams have been provided in FIGS. 1-17, whose redundant description has not been duplicated in the related description of analogous circuit-related diagrams. It is expressly incorporated that the same diagrams with identical symbols and/or reference numerals are included in each of the embodiments based on its corresponding figure(s).

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the claimed invention. Alternatively, or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the claimed invention. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, where such instructions may execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A circuit comprising:
at least one flip-flop; and
clock-sharing circuitry comprising a clock-controlled transistor device coupled to at least one shared node of the at least one flip-flop, wherein the at least one shared node comprises at least one of:
an intra-flop shared node coupled between two or more logic structures within the at least one flip-flop; and
an inter-flop shared node coupled between at least two flip-flops.

2. The circuit of claim 1, wherein the at least one flip-flop comprises:
a master latch comprising cross-coupled logic structures, wherein at least one logic structure is clock-gated and integrates an input multiplexer; and
a slave latch comprising a tristate driver and a feedback storage loop coupled to the cross-coupled logic structures.

3. The circuit of claim 2, wherein:
the master latch comprises keeper sub-circuitry coupled to an output node of the master latch; and
the keeper sub-circuitry is configured to retain a predefined logic state at the output node.

4. The circuit of claim 1, wherein the clock-sharing circuitry comprises at least one of:
a NAND-based logic structure comprising a shared foot transistor coupled at a bottom-most transistor position and configured to couple to a low power supply; or
a NOR-based logic structure comprising a shared head transistor coupled to an inverted clock signal and positioned at a top-most transistor position of a NOR transistor stack.

5. The circuit of claim 1, wherein the intra-flop shared node is coupled between a master latch and a slave latch within the at least one flip-flop.

6. The circuit of claim 1, wherein the inter-flop shared node is coupled across the at least two flip-flops to eliminate redundant clock-controlled transistors in a multi-bit configuration.

7. The circuit of claim 6, wherein the clock-sharing circuitry comprises a shared clock inverter configured to generate an inverted clock signal provided concurrently to each flip-flop of the at least two flip-flops.

8. The circuit of claim 1, wherein the clock-sharing circuitry comprises a NAND-based configuration, wherein:
the clock-controlled transistor device comprises a shared foot transistor positioned at a bottom-most transistor stack of each NAND-based logic structure; and
the shared foot transistor is coupled to a low power supply node.

9. The circuit of claim 8, wherein the shared foot transistor is coupled across multiple cross-coupled NAND gate structures of respective flip-flops to provide inter-flop transistor sharing.

10. The circuit of claim 1, wherein the clock-sharing circuitry comprises a NOR-based configuration, wherein:
the clock-controlled transistor device comprises a shared head transistor positioned at a top-most transistor stack of each NOR-based logic structure; and
the shared head transistor is coupled to a high power supply node.

11. The circuit of claim 10, wherein the shared head transistor is coupled across multiple cross-coupled NOR gate structures of respective flip-flops to provide inter-flop transistor sharing.

12. The circuit of claim 1, wherein the clock-controlled transistor device is coupled to at least two logic structures comprising cross-coupled NAND gates or cross-coupled NOR gates within a same flip-flop to enable intra-flop transistor sharing.

13. The circuit of claim 1, wherein the clock-sharing circuitry simultaneously provides intra-flop transistor sharing within individual flip-flops and inter-flop transistor sharing across multiple flip-flops.

14. The circuit of claim 1, wherein each flip-flop comprises a slave latch, and wherein the slave latch comprises a tristate driver with integrated keeper functionality configured to maintain node stability without using a separate keeper transistor device.

15. The circuit of claim 1, further comprising:
clock inverter circuitry configured to generate an inverted clock signal from an input clock signal, wherein the inverted clock signal is coupled concurrently to the at least two flip-flops.

16. The circuit of claim 15, wherein the clock inverter circuitry is positioned within the circuit and configured to directly drive transistor gates of the at least two flip-flops.

17. The circuit of claim 1, wherein each flip-flop comprises a first NAND-based logic structure with an integrated scan multiplexer circuit coupled to an input of the flip-flop.

18. The circuit of claim 1, wherein the clock-controlled transistor device is coupled to a shared clock-control node coupled across a plurality of flip-flops, and wherein the clock-controlled transistor device is positioned at a bottom-most transistor position of a NAND-based logic structure or at a top-most transistor position of a NOR-based logic structure.

19. The circuit of claim 18, wherein the shared clock-control node is coupled to a clock distribution network, and wherein the clock-sharing circuitry provides a total transistor load of (2N+1) to the clock distribution network, where N corresponds to a number of flip-flops coupled to the shared clock-control node.

20. The circuit of claim 18, wherein the clock-controlled transistor is coupled to multiple clocked nodes across different flip-flops.
